(19) United States
(12) Patent Application Publication
(10) Pub. No.: US 2025/0194268 A1
(43) Pub. Date: Jun. 12, 2025

(54) PROTOCOL FOR THINNING THE REAR SUBSTRATE OF INDIVIDUAL CHIPS ATTACHED BY HYBRID BONDING OF DIE-TO-WAFER TYPE

(71) Applicant: COMMISSARIAT A L'ENERGIE ATOMIQUE ET AUX ENERGIES ALTERNATIVES, Paris (FR)

(72) Inventors: Renan BOUIS, Grenoble (FR); Emilie BOURJOT, Grenoble (FR); Carine LADNER, Grenoble (FR)

(73) Assignee: COMMISSARIAT A L'ENERGIE ATOMIQUE ET AUX ENERGIES ALTERNATIVES, Paris (FR)

(21) Appl. No.: 18/969,370

(22) Filed: Dec. 5, 2024

(30) Foreign Application Priority Data
Dec. 8, 2023 (FR) FR2313880

(51) Int. Cl. H10F 39/00; H01L 23/00; H10F 39/95

(52) U.S. Cl. CPC H10F 39/026; H01L 24/80; H10F 39/95; H01L 2224/80895; H01L 2224/80896

(57) ABSTRACT

A method produces a microelectronics device by hybrid bonding of individual chips onto a handle wafer, of the Die-to-Wafer type, includes a flow protocol for thinning the rear substrate of the chips. The flow protocol includes a pre-thinning grinding of the rear substrate of the individual chips once they have been attached to the wafer. This grinding is preceded by the formation of a protective layer protecting the trenches formed by the spaces between the attached individual chips. Next, a rectification etching rectifies the height of the rear substrate of each of the attached individual chips, via chemical wet etching, to eliminate the Total Thickness Variation. This etching is selective with respect to an etch-stop element contained in the respective substrates of the attached chips and which is used to stop the etching at a level that is substantially uniform for each of the chips.

### TECHNICAL FIELD OF THE INVENTION

The invention relates in general to the field of the microelectronics industry and is more particularly concerned with the three-dimensional (3D) integration of microelectronic devices, the term “microelectronic devices” referring to devices including devices obtained using nanotechnologies.

The invention proposes a method for producing a microelectronics device using 3D assembly of individual chips by hybrid bonding onto a semiconductor wafer, also referred to as a “handle” wafer by reference to its function of supporting the chips thus bonded, the method comprising an improved flow protocol for thinning (grinding) the rear substrate of the inverted individual chips, this being something that is done once the attached individual chips have been transferred onto the handle wafer.

It finds applications, notably, in the manufacture of high-performance components and micro systems, such as micro-electromechanical systems (MEMS) or nano electromechanical systems (NEMS), actuators, radiofrequency (RF) components, power devices or microelectronic or optoelectronic devices such as, for example, image-capturing devices (or imagers) using CMOS (complementary metal-oxide-semiconductor) technologies or the like.

### TECHNICAL BACKGROUND

3D integration consists in assembling microelectronics devices vertically by bonding in a three-dimensional (3D) structure, rather than being confined to a planar two-dimensional (2D) structure, but using only 2D process flow protocols to create the two devices separately. It relies on bonding, one on top of another, microelectronics devices each designed on a respective semiconductor substrate, and each having a planar structure the respective surfaces of which have been ultra-polished, and one of which is inverted for the purpose of being bonded to the other device.

More particularly, the respective surfaces of the microelectronics devices that are to be stacked, by means of which surfaces these devices are superposed, have dedicated bonding zones, for example metallic zones or HBMs (Hybrid Bonding Metallizations) which are insulated using a dielectric material. These zones may or may not be electrically connected to transistors or other active or passive elements previously produced beneath the surface of each of said devices, using vertical connections (also known as TSVs or Through Silicon Vias when the substrate is silicon-based) that pass through this substrate of said devices. If the two devices are assembled vertically one against the other, the respective bonding zones of the two devices come into contact with one another establishing, where applicable, vertical electrical connections between elements of these devices, through the various layers. As a variant or in addition, vertical conducting connections that pass through the substrate of the upper device may be made after bonding so as to allow electrical connection between the various functional elements of the two stacked devices. Thus, vertical assembly of the two stacked devices by inverting one and bonding it to the other (a technique also known as the flip chip technique) allows these two devices to communicate with one another directly through short vertical electrical connections established through the bonding interface, thereby avoiding any external (wire-bonding) connection. Reducing the lengths of the interconnections increases the speed of communications between the various functional elements of the devices thus assembled, and reduces the dissipation of energy through the Joule heating effect, and therefore reduces the rise in temperature.

There are various technical methods in existence for achieving 3D assembly, and these can be adapted differently to suit the specific requirements of the target applications. These methods are applicable to the bonding to a handle wafer, with or without an intermediate layer, both of semiconductor wafer(s) on which chips have been produced (such a wafer is then referred to as a “product” wafer) and of individual chips (die/dices). The terminology used is Wafer-to-Wafer (W2W) bonding or chip-to-wafer/Die-to-Wafer (D2W) bonding, respectively. Of course, the number of layers of stacked devices is not restricted to two. It is always possible to add an nth layer of device(s) on top of a stack of devices that have already been assembled vertically, provided that the upper surface of said stack, which is the surface intended to receive the new device(s), is sufficiently clean, flat and smooth. If it is not, bonding defects, which is to say non-bonded zones referred to as voids, i.e. interface bubbles, may arise.

The direct advantage of 3D integration lies in the reduction in the surface area of the microelectronics device obtained. 3D integration thus responds to a need to increase the compactness of microelectronic circuits by allowing the devices to be stacked vertically thus allowing more functionalities to be integrated onto the one same surface area of substrate.

However, 3D integration also indirectly affords a great many other advantages. It thus allows the functional device obtained greater efficiency, notably having a higher communication speed and a lower energy requirement, as mentioned above, because of the high density of, and shortening of the interconnections between, the stacked devices. It also allows hybridization of technologies, since the functionalities can effectively be distributed over different devices intended to be stacked, and these devices can then be produced separately using on-substrate production technologies which are specific to each of the devices. It is thus possible, for example, to choose the fineness of the etching, the design rules or planar production solutions specific to each of the devices, before assembling them vertically using bonding. This may also be referred to as heterogeneous 3D integration.

3D integration calls upon numerous technological skills, because of the complexity of implementing it. It notably requires proficiency in the following key technological building blocks:
the assembly of the various wafers or chips using an ad-hoc bonding method, which assembly notably comprises an aspect associated with the detaching of the device that is to be transferred from its original support, as well as an aspect associated with the constraints of aligning said device on the destination support (i.e. the handle wafer);
the thinning of the rear substrate of the attached device(s), which is to say the substrate of the inverted upper device, once the devices have been assembled by bonding, so as to reduce the thickness and, where applicable, allow the 3D integration to continue; and
the creation of the vertical connections or vias (TSVs) between the vertically stacked devices after they have been assembled by bonding, passing through the substrate of the upper device to allow electrical connection between the various functional elements of the stacked devices, these vertical connections needing to be made with particular constraints (notably a reduced use of temperature) so as not to damage the bonding interface of the stacked devices.

In order to perform a transfer of D2W type, assembly involves prior detachment, from their original substrate, of the individual chip(s) to be transferred. This step is also referred to as individualization (or singulation). Assembly also involves adding inverted individual chips, with the chips being collected and placed in an inverted position, this step being performed by the head of a component pick and place tool.

The present invention more particularly addresses the problem of thinning the substrate of the transferred chip(s), which thinning is performed after the addition, by bonding of D2W type, of the individual microelectronic devices thus attached to the handle wafer.

In nonlimiting applications of the invention that will be considered here, recourse to 3D integration is intended for vertically assembling, by bonding, on the one hand, a support device that uses standard CMOS technology, on the bottom, and, on the other hand, a plurality of photosensitive elements (for example photodiodes) of an optoelectronics device such as a CMOS imager, on the top, to form the array of photosensitive elements of the imager.

Imagers manufactured in this way, known as BackSide Illumination (BSI) imagers are widely used nowadays because of their specific advantages. These advantages include a better fill factor (defined as being the ratio of the surface area of the light-capturing zone to the total surface area occupied by the silicon substrate) and a better capture of light, compared with front side illumination imager technologies. They are particularly advantageous in applications in which there may be partial sunlight or other low-light conditions. BSI imagers were initially used in specific fields requiring a highly light-sensitive array, for example in low-light security cameras, microscope cameras and astronomy systems, to name but these few examples. The progress this technology has achieved now allows it to be used in electronics for the general public, for example to create cameras integrated into small devices available to the general public, such as smartphones. In this type of application, the camera generally uses backside illumination CMOS technology active pixel sensors, also known as BSI-CMOS imagers.

In order to produce such a BSI-CMOS imager, there is a known hybrid bonding method for creating an imager comprising photodiodes bonded to a traditional CMOS wafer in which a network of metal interconnections has been produced in order to act as the wiring for the photodiodes. The bonding is of the W2W type, an array of photodiodes being transferred with a product wafer on which the photodiodes have been produced. This technology makes it possible to obtain a BSI-CMOS device in which the active array of the CMOS imager, namely an array of photosensitive elements referred to as “pixels” (this term being a contraction of the expression “picture element”) embodied by photodiodes, is arranged on the upper surface (the surface that receives the incident light), while the wiring of the array is arranged behind the layer of photodiodes of the active array. This result is obtained by inverting the product wafer during the course of manufacture and bonding it onto the handle wafer, then by thinning the rear substrate, which is to say the substrate on the back side of the inverted product wafer (grinding step), so that the light can reach the photodiodes layer without passing through the wiring layer. The smaller the size of the pixels, the greater the gain, in terms of fill factor, that is obtained by thus moving the photodiode wiring from the upper surface of the product wafer to the lower surface of the microstructure.

Nevertheless, if one or more of the photodiodes are unusable as a result of some defect that has occurred during their production inside the wafer on their original semiconductor wafer (i.e. on the product wafer), then performing the bonding serves no purpose because there is a risk that the device obtained will not be operational, or at least will not operate optimally. A photodiode that is defective may yield a black pixel in the digital image acquired by the imager.

According to a novel approach, the desire is therefore to perform a D2W-type assembly of the photodiodes by way of individual chips, so that the chips can be triaged before they are added to the wafer, thus providing the possibility of eliminating non-functioning chips (i.e. of adding only functioning chips, the correct functioning of which has been verified), something that is not possible to achieve with bonding of the W2W type.

One particular difficulty stems from the wide Total Thickness Variation (TTV) of the chips attached by bonding to the handle wafer, which variation is inherently introduced by the collective thinning of the chips by grinding, whereby the thickness of the attached chips is reduced from around 775 μm to around 15 to 25 μm. Such a result of grinding is, however, obtained at the expense of a significant worsening of the TTV, since this grinding introduces significant differences in height between the individual chips. Once the grinding is complete, an additional, less aggressive, thinning operation has to be performed by polishing the rear substrate of the inverted photodiodes bonded on top of the standard CMOS wafer in order to remove the work-hardened zone induced by the grinding. This entails a great many Chemical and Mechanical Polishing (CMP) steps.

Admittedly, CMP is a viable technology for creating planar surfaces by performing overall flattening (planarization) of the topographies resulting from the processing operations that are conventionally performed in industrial microelectronics (deposition, lithography, etching, etc.). In particular, the overall planarization of the chips is performed using a layer of oxide (or more generally of a mineral material) that has been formed on top of the wafer to fill the spaces between the chips to make CMP planarization easier. However, some of these processing operations are nevertheless fairly difficult to carry out in practice, bearing in mind, as applicable, the topography of the surface that is to be polished and/or the nature of the materials that are to be attacked in order to perform this polishing, something that is the case in the application envisioned here of post-grinding polishing of the rear substrate of individual chips attached by D2W bonding.

In short, there is a need for a “process flow” protocol that enables a microelectronic device to be produced by hybrid bonding of Die-to-Wafer (D2W) type, by bonding individual chips corresponding, for example, to photodiodes that form the active cells of an imager, onto a handle wafer that may be a wafer for the wiring of said active cells of the imager, rather than bonding a semiconductor wafer (product wafer) comprising a unit array of such photodiodes onto the handle wafer using Wafer-to-Wafer (W2W) bonding.

One difficulty lies in the fact that the thinning of the rear substrate of the attached individual chips, which is performed using conventional grinding operations after a hybrid bonding of D2W type, causes such a total thickness variation (TTV) in the chips after grinding that the polishing operation that has to be performed thereafter using CMP is complicated to implement. Specifically, the height differences between the attached chips that result from the grinding (and that are estimated at around 2.5 μm or more, at the very least) cannot be erased, which is to say effaced, by this means without greatly adding to the complexity of the CMP flow protocols employed. It appears necessary, at the very least, to protect or even repair the structures not involved in the thinning, notably the metallizations at the bonding interface in the spaces between the attached chips.

A person skilled in the art will appreciate that the aforementioned requirement, although presented hereinabove in the context of the manufacture of a CMOS imager by hybrid bonding of individual photodiodes, may be encountered in the production of a great many other microelectronic circuits, where there is a need to thin the rear substrate of any type of microelectronic device attached by D2W type bonding. The solution proposed here, according to embodiments of the invention, may therefore be able to be applied in diverse microelectronics applications which are multiple and varied.

Document US20180301365A1 discloses the D2W-type bonding of individual chips of different thicknesses onto a silicon wafer. It is mentioned that the chips may be manufactured and undergo singulation with a flattened oxide layer the purpose of which is to protect the metallized rear structures. The front faces of the chips are then bonded to a first handle wafer so that the respective structures are aligned in a common plane. The material of the substrate of the rear faces of the bonded chips is then thinned down until a uniform thickness is achieved, and then bonded to a second handle wafer once a further protection has been applied. The assembly thus obtained is then inverted, and the first handle wafer together with the protective layer comprising potential dicing and handling debris are removed. The posterior structures are then revealed, resulting in a composite assembly comprising the second handle wafer and one or more uniformly thinned chips which are bonded thereto, enabling further steps of assembly by bonding.

Document SG177817A1 relates to the proprietary SmartCut™ method, which involves the implantation of ions and a splitting anneal. Methods for manufacturing semiconductor structures comprising the implantation of atomic species in a carrier matrix or a wafer in order to form a weakened region in the carrier matrix or the wafer, and the bonding of the carrier matrix or of the wafer to a semiconductor structure are disclosed. The semiconductor structure may be processed using the support or the wafer for manipulating the semiconductor structure. The semiconductor structure may be bonded to another semiconductor structure, and the supporting wafer or matrix may be divided along the weakened region it contains. Bonded semiconductor structures manufactured using these methods are also disclosed.

Document US2023154914A1 discloses a method for creating an entity comprising a temporary wafer and one or more tiles fixed removably to said temporary wafer, preferably via a temporary adhesive layer. The tiles comprise a support part and an active-material part. The active-material part is fixed to the temporary support. The entity further comprises a single continuous layer of the first material surrounding each of the one or more tiles. After being flattened at the rear, the tiles and the continuous layer of the first material are attached to a permanent supporting wafer, after which the temporary supporting wafer is removed. The method makes it possible to obtain a hybrid wafer comprising a planar upper layer formed of the material of the continuous layer with one or more islets embedded in it, the upper layer of said islets being formed by the upper layer of the active-material part of the tile or tiles.

The scientific article by D. Zhuang and J. H. Edgar, entitled “Wet etching of GaN, AlN, and SiC: a review”, Materials Science and Engineering: R: Reports, Volume 48, Issue 1, 2005, Pages 1-46, ISSN 0927-796X, https://doi.org/10.1016/j.mser.2004.11.002, reviews the wet-etching of GaN, AlN and SiC, including conventional etching in aqueous solutions, electrochemical etching in electrolytes and defect-selective chemical etching in molten salts. The mechanism of each etching process is discussed. The etching parameters leading to highly anisotropic etching, to dopant-type/bandgap selective etching, to defect-selective etching and to isotropic etching are examined. The etch pit shapes and their origins are examined. The applications of wet etching techniques to characterize crystal polarity and defect density/distribution are examined. Additional applications of wet etching for device fabrication, such as producing crystallographic etch profiles, are also examined.

Document US20060068586A1 discloses the process for manufacturing BSI CMOS imagers with a buried oxide layer by way of passivation layer.

### SUMMARY OF THE INVENTION

The objective of the invention is to overcome, at least partially, the above-mentioned disadvantages of the prior art, and more particularly to offer an alternative to the known process flow protocols for thinning the rear substrate of microelectronics devices attached by bonding of the Die-to-Wafer (D2W) type, after inverting and bonding to a handle wafer.

In order to achieve that, one subject of the invention is a method for producing a microelectronics device, involving hybrid bonding of a plurality of individual chips which are inverted vertically and then attached by bonding to a semiconductor wafer, or handle wafer, the method comprising, after the attached individual chips have been bonded to the handle wafer, a flow protocol for thinning the rear substrate of the individual chips attached to the handle wafer, which comprises:
a pre-thinning grinding of the rear substrate of the individual chips attached to the handle wafer, preceded by the formation of a first protective layer protecting the trenches formed by spaces between the individual chips attached to the handle wafer, which are not affected by said pre-thinning grinding;
followed by rectification etching to rectify the height of the rear substrate of each of the individual chips attached to the handle wafer, this being performed by chemical wet etching of said substrates, said chemical wet etching being selective with respect to an etch-stop element contained in the substrates and which is used to stop the etching at a level that is substantially uniform for each of said chips.

In other words, the method makes it possible to produce a semiconductor product by a 3D assembly of type D2W. Advantageously, the individual chips attached may therefore be triaged beforehand, on the basis of the results of a test performed on each one of them, so as to set aside any chips that are not functional and attach to the “handle” substrate by bonding only chips that are functional. The test may be a test of correct electrical functioning of each chip that is to be attached. This then avoids the risk of a chip that is non-functional going on to cause the non-functioning, in its entirety, of the microelectronics device that incorporates it after 3D assembly.

Unlike the thinning processes of the prior art in which the thinning is performed by one or more successive chemical mechanical polishing (CMP) steps, possibly alternating with steps of repairing and/or of filling in portions of the microstructure that have become damaged during the course of production, the method according to the embodiments makes a distinction between, on the one hand, the actual thinning grinding of the rear substrate of the attached individual chips, and, on the other hand, the rectification of the height of the attached individual chips, specifically by having very distinct processing steps and methods. More particularly, a “pre-thinning” is performed first of all using grinding, and this is followed by a rectification which is performed chemically, notably by chemical wet etching.

In other words, the invention breaks with the existing precedent of the prior art whereby the grinding is supposed to achieve both, on the one hand, the thinning per se, enabling substantial (but relatively uniform) reduction in the thickness of the rear substrate of the microelectronics device(s) attached by bonding and, on the other hand, the rectification (or “planarization”) of the upper surface of the vertical stack resulting from the grinding, so as to smooth this surface by eliminating any thickness variation. Specifically, while such a single process with this dual objective is admittedly generally satisfactory for thinning the rear substrate of a product wafer attached to a handle wafer by W2W bonding, it is far less satisfactory for rectifying the total thickness variation (TTV) after individual chips have been diced from a donor wafer and added by D2W type bonding to a handle wafer. In terms of terminology, and in order to highlight the contribution and specifics of the invention, the text that follows makes a distinction between, on the one hand, “pre-thinning grinding” which leaves the ground surface with a relatively coarse level of flatness but which is relatively quick to perform and, on the other hand, “surface rectification etching” or “surface planarization etching”, which is relatively more effective in terms of the planarity obtained, but which is relatively slower to perform. A person skilled in the art will appreciate that the relative slowness of rectification etching can be compensated for by the fact that it can be performed collectively on an entire batch of wafers, unlike the grinding which is performed wafer by wafer.

The first protective layer, for example based on silicon nitride (SiN1), is formed over the top of the entirety of the microstructure after the bonding of the individual chips and before the pre-thinning grinding is performed. The conforming protective layer thus obtained prevents the surface of the handle wafer from becoming contaminated during the grinding. Such contamination is effectively liable to be caused by the ingress of grinding fluid and/or grinding debris, notably in the bottom of the spaces between the attached individual chips, at the interface with the handle wafer.

A second protective layer may also be deposited over the top of the entirety of the structure after the pre-thinning grinding and before the chemical wet rectification etching is performed. For example, a conforming second layer based on silicon nitride (SiN2) may be deposited in a similar way to the first deposition of SiN1. Since the first protective layer SiN1 may possibly have become damaged by the pre-thinning grinding, the second protective layer SiN2 repairs it so as to maintain the effectiveness of the protection of the microstructure, with a view to rectification etching, against the chemical compounds used for this etching. This protective layer SiN2 compensates for the highly isotropic nature of the rectification etching, which is ideally a chemical wet etching, performed using an acid solution, because of the selectivity that this type of etching allows.

Certain preferred but nonlimiting aspects of the method are as follows.

The method may further comprise, between the pre-thinning grinding and the rectification etching, the formation of a second protective layer protecting the trenches formed by the spaces between the individual chips attached to the handle wafer, which are not affected by said rectification etching.

In that case, the method may also further comprise the removal of the second protective layer only at the planar portions of the rear substrate of the attached individual chips, by etching through a mask obtained beforehand by photolithography of a layer of photosensitive resin, in order to selectively uncover the rear substrate of said chips so that these can undergo the chemical wet rectification etching.

In some embodiments, the material of the first protective layer and/or the material of the second protective layer may be materials based on a nitride, notably based on silicon nitride.

The chemical wet rectification etching may for example be performed using, by way of etch-stop elements, a zone that has a particular doping in the rear substrate of each of the attached individual chips, which zone is created in said substrates at a determined depth, which depth is substantially identical for each of said chips.

For example, the particular doping of the zone of the rear substrate of each of the attached individual chips that is used as the etch-stop element for the chemical wet etching may then be a P-type doping different from the standard P-type doping of said rear substrate.

In other embodiments, with the rear substrate of each of the attached individual chips being a composite substrate, the chemical wet rectification etching may be performed using, by way of etch-stop elements, a layer of the composite substrate of each of the attached individual chips, which layer is made of a specific material at a determined depth in said composite substrates, which depth is substantially identical for each of said chips.

For example, the specific material from which the etch-stop elements for the chemical wet rectification etching are produced may then be a material based on gallium arsenide (GaAs) or based on aluminium (Al).

In other embodiments, with the rear substrate of each of the attached individual chips being an epitaxial silicon substrate a few microns thick, the chemical wet rectification etching may be performed using, by way of etch-stop elements, a thin layer of the epitaxial silicon substrate of each of the attached individual chips, which layer is made of a specific material at a determined depth in said substrates, which depth is substantially identical for each of said chips.

For example, the thin layer used as etch-stop element for the chemical wet rectification etching may then be a thin layer of silicon oxide or a thin layer of silicon nitride.

In other embodiments, with the rear substrate of each of the attached individual chips being a Silicon-on-Insulator, or SOI, substrate, the chemical wet rectification etching is performed using, by way of etch-stop elements, a buried layer buried in the SOI substrate of each of the attached individual chips, which layer is made at a determined depth in said SOI substrates, which depth is identical for each of said chips.

For example, the buried layer in the SOI substrate of each of the attached individual chips, which layer is used as etch-stop element in the chemical wet rectification etching, may be a Buried Oxide, or BOX, layer of said substrate.

In some embodiments, the attached individual chips may be chips that have previously been diced from the one same single donor semiconductor wafer.

In some embodiments, the handle wafer may be a wafer made using traditional CMOS technology.

In some embodiments, the pre-thinning of the rear substrate of the individual chips attached to the handle wafer may be performed using grinding.

In some embodiments, the pre-thinning of the rear substrate of the individual chips attached to the handle wafer may be performed using a method known by the name of SmartCut™ comprising the implantation of ions and a splitting anneal.

In some embodiments, the individual chips may be triaged, prior to being added to the handle wafer, on the basis of the results of a test, so as to set aside any chips that are not functional and add to the handle wafer by bonding only chips that are functional.

For example, the test may be a test of correct electrical functioning of the chips.

Another subject of the invention is a colour imager of BSI (BackSide Illumination) type, comprising a microelectronics device with an array of photosensitive elements, wherein:
the photosensitive elements are individual chips attached to a semiconductor wafer, or handle wafer; and
the rear substrate of the individual chips attached to the handle substrate has been processed by implementing the method according to the first aspect hereinabove,
the imager further comprising an array of colour filters and an array of microlenses which are produced over the top of the microelectronics device.

In this nonlimiting example of an application of the method, the individual chips concerned comprise photosensitive elements (photodiodes) which, once the chips have been attached to the surface of the handle wafer, are surmounted by colour filters and microlenses, so that each chip provides one pixel of the imager. The imager is, for example, a back-side illuminated CMOS, also known as a BSI-CMOS, colour imager. In applications such as this one, recourse to 3D assembly according to the method conforming to the proposed solution allows individual chips, that have previously been electrically tested, to be connected by bonding to create an imager on a handle substrate already comprising a microelectronics device (for example one using CMOS technology) in which a metal interconnections network has been formed for wiring the photodiodes and/or their control transistors.

### INTRODUCTION TO THE DRAWINGS

Other aspects, aims, advantages and features of the invention will become more clearly apparent on reading the following detailed description of preferred embodiments thereof, which is given by way of non-limiting example and with reference to the appended drawings, in which:

FIG. 1A and FIG. 1B are views in cross section of, respectively, an example of a handle wafer and an example of an individual chip, said individual chip being suitable for being attached, after vertical inversion, to said wafer by D2W-type bonding;

FIG. 2 is a view in partial section of a colour pixel of a BSI-CMOS imager incorporating a photosensitive microelectronics device comprising the chip of FIG. 1B attached to the handle wafer of FIG. 1A, and after additional steps have been performed in order to create, notably, colour filters and microlenses;

FIG. 3 is a partial view from above of a BFI-CMOS imager comprising an array of pixels such as the pixel of FIG. 2;

FIG. 4 is a functional diagram featuring schematically, with views in cross section, the principle of D2W-type assembly of a microelectronics device, and also illustrating the problem at the root of the invention and the result expected of the solution according to embodiments of the invention; and

the figures of FIG. 5A to FIG. 5M illustrate how an example of a microstructure evolves following the execution of the various steps, respectively, of a process flow protocol according to embodiments of the invention.

### DESCRIPTION OF THE EMBODIMENTS

In the figures and in the remainder of the description, the same references designate elements that are identical or similar. In addition, the various elements are not shown to scale so as to make the figures clearer. Moreover, and unless explicitly indicated otherwise, the various embodiments and variants set out are not mutually exclusive and may where applicable be combined with one another.

The term “wafer” denotes a very thin sheet (or slice) of monocrystalline semiconductor material on which microelectronics devices can be produced. Wafers are thus used for manufacturing microelectronics components, such as imagers. The wafers are produced from a doped semiconductor material such as silicon (Si), gallium arsenide (GaAs) or indium phosphide (InP). Wafers have dimensions generally comprised between 25.4 mm and 300 mm in diameter, for a thickness of the order of 0.7 mm. Wafers are used in the microelectronics industry as supports on which to manufacture microstructures. This manufacture employs production techniques such as, for example and nonlimitingly, doping, etching, the deposition of other materials, and photolithography. The doped semiconductor material from which the wafer is made therefore acts as a substrate for the creation of the microstructures that form the microelectronics devices used in the composition of integrated circuits, transistors, power semiconductors or MEMS/NEMS, etc.

In what follows, the terms “substantially”, “approximately” or else “of the order of” mean to within 10%, and preferably to within 5%. Moreover, the terms “comprised between . . . and . . . ”, or equivalent terms, mean inclusive of endpoints, unless explicitly mentioned otherwise.

The expression “formed on the basis of”, when used with reference to a material and to an element of interest, means that the material is a composite formed of a plurality of elements including at least said element of interest.

The expression “material containing predominantly” an element of interest means a material of which at least 50% by volume is formed of or contains said element of interest.

The term “anisotropic etching”, used with reference to a determined material, means that the rate of etching of said material is not the same in all directions during the etching process. Rather, etching takes place essentially in just one single direction, which is generally the vertical direction (namely the direction orthogonal to the plane in which the surface of the material that is to be etched extends). Stated differently, during such an etching process, the structure is not etched, or is etched only a little, in any arbitrary lateral direction. By contrast, “isotropic etching” does not favour any particular direction of etching, which means that all of the exposed surfaces are etched simultaneously, regardless of their orientation in space, i.e. whether they be horizontal, vertical or inclined.

The expression “Chemical-Mechanical Polishing” (or CMP), already used in the introduction, means a process of smoothing the surface of a wafer using the combined action of chemical and mechanical forces, with the effect of removing material(s) from the surface of the wafer and of effacing any surface topography, with the result of planarizing the surface of the wafer exposed to this process.

The term “grinding” means a process of thinning the rear substrate of a semiconductor wafer to a desired thickness, this thinning being obtained is essentially mechanically by pressing the wafer against a table in relative rotation (referred to as grinder) while being sprayed with a grinding fluid. By providing a plurality of elements that regulate the mechanical pressure and that are correctly incorporated into the thickness of the material that is to be ground, and the surfaces of which are more resistant to grinding than the other surfaces of the wafer, the wafer obtained after thinning has the desired thickness.

The term “rectification” means a finishing operation that comes after the grinding of a semiconductor wafer, with the objective of finishing the planarity of the ground surface, making it possible to achieve very tight tolerances, smaller than ten nanometres or so for the total thickness variation of the wafer. When, as in this instance, the total thickness variation of the wafer is due to differences in height between individual chips attached to said wafer which was itself suitably planar, reference may also be made to correcting the thickness variation of these attached chips.

Where applicable, namely where necessary for understanding embodiments of the method, a distinction will be made between, on the one hand, the actual thinning grinding (referred to as “pre-thinning grinding”) of a microstructure, which produces substantially nothing more than a uniform reduction in the thickness of the various elements of the microstructure and, on the other hand, the surface rectification which provides planarization of the upper surface of the microstructure by making the height of the elements in question uniform, i.e. by erasing the total thickness variation, or TTV of the wafer, which is the result of the spread on the respective heights of the individual chips attached to the wafer.

Finally, here, and for the rest of the description, an orthogonal three-dimensional direct frame of reference (X, Y, Z) is defined, where the axes X and Y form a plane parallel to the main plane of the “handle” wafer concerned, and where the axis Z is oriented substantially orthogonal to the main plane of the wafer, this axis Z being oriented in the direction of the axis of gravity. In the remainder of the description, the terms “vertical” and “vertically” are to be understood as relating to an orientation substantially parallel to the axis Z, and the terms “horizontal” and “horizontally” as relating to an orientation substantially parallel to the plane (X, Y). Moreover, the terms “top” and “bottom” and associated terms (such as “above” and “beneath”, or “on top of” and “underneath”) and also the terms “lower” and “upper”, where used to qualify an element of the microstructure concerned, are to be understood as being relative to a position that increases with increasing distance from the wafer in an upward direction, i.e. in the +Z vertical direction.

The term “rear” and the term “front” on the other hand are used with reference to that face of a wafer via which the various processing operations are, or have been, performed in order to create the microstructure concerned. These processing operations being systematically performed from the top when the wafer is lying flat in an enclosure used for performing the process, the “front” face is generally (and by default) the upper face of the wafer. However, when a wafer or a chip diced from a wafer is inverted vertically, its front face becomes the lower face and its rear face becomes the upper face. The qualifier “rear” when applied to the semiconductor substrate of a wafer or of an individual chip also follows this convention, in that it refers to that part of the substrate that is furthest away from the face of said wafer or of said chip where the processing operations have been performed on the substrate, and that it is always qualified as the face even when the wafer or the chip has been vertically inverted.

Particular embodiments of the hybrid bonding method of D2W type will be described with reference to the nonlimiting example of the application of the method to the manufacture of a microelectronics device such as a digital image sensor (or “imager”). Such a sensor is produced on the basis of photosensitive microelectronics devices, i.e. devices suited to capturing light and converting it into electrical current. They are based on photodetectors such as, for example, photodiodes using CMOS technology. They are operated in conjunction with microlenses, and also colour filters if the sensor is a colour digital image sensor. One or more such photosensitive devices thus supplemented correspond to a picture element, or pixel.

The ratio of the light-sensitive surface area of a pixel to the total area that the pixel occupies at the surface of the semiconductor substrate on which it is produced is referred to as the “fill factor”. CCD (“Charge-coupled Device”) sensors have a fill factor close to 100%. In CMOS sensors, it was originally around 50 to 70%, but with the miniaturisation of transistors and the use of microlenses (by virtue of which a greater surface area of the pixel contributes to collecting photons), the fill factor of CMOS sensors has greatly improved.

Most imagers which are made up of large-sized pixels (i.e. pixels with a side length in excess of approximately 3 μm) are illuminated from the front side face. Because of their large size, the front side face of the pixels is relatively unencumbered by the metallic interconnections and the transistors of the reading system produced above it. These pixels therefore experience no problem in collecting light, even from a high angle of incidence. They therefore have a fairly high fill factor, in the region of 80 to 90%. In the case of sensors incorporating pixels with a side length less than or equal to 2 μm, on the other hand, backside illumination becomes essential for obtaining a photosensitive surface that is as unencumbered and extensive as possible. A sensor with BackSide Illumination, (or BSI sensor), is a type of digital image sensor that uses a particular arrangement of imaging elements, obtained notably by adding photodiodes that form the array of optical sensors to a “handle” wafer so as to increase the quantity of light captured and thus improve the low-lighting performance of the imager. This technological building block makes it possible to obtain fill factors ranging to as high as 100%. It also brings with it a reduction in the thickness of the stack of optical layers (microlens, colour filters and antireflective coating) and a greater flexibility in the design of the metallic interconnections.

The example will more particularly consider a backside illuminated CMOS imager, also referred to as a BSI-CMOS imager. Such an image is an optoelectronics device comprising image sensor elements (i.e. “pixels”) produced using CMOS-technology photodiodes. The sensors are active elements suited to capturing photons when associated with microlenses. Where applicable, they may also be associated with colour filters for capturing a colour digital image, and possibly with an antireflective coating.

In this example of an application of the method, the individual chips that are the subject of the hybrid bonding are photosensitive microelectronics devices intended to form the pixels of a CMOS colour imager, namely an imager capable of capturing colour digital images of a scene. Each of these chips comprises at least three photosensitive elements, each one sensitive to white light, which are intended to be associated with respective elementary colour filters corresponding to one primary colour of a determined trichromatic system, such as the RGB (Red, Green, Blue) system that this photosensitive element is to detect. These chips are detached from a “product” wafer on which they have been produced. They are then inverted and attached by hybrid bonding of D2W type to a “handle” wafer which serves as their operational support, and which is for example produced using traditional CMOS technology.

However, it goes without saying that the embodiments described are also suited to the manufacture of other integrated microelectronics devices, notably different optoelectronics devices and/or devices designed in a different way or using a different technology, MEMS or NEMS, or any other microelectronics devices, be they active or passive.

The embodiments relate more particularly to the phase of thinning the rear substrate of the individual chips after they have been inverted and then attached to the handle wafer using hybrid bonding of D2W type. Such thinning forms an integral part of the hybrid bonding 3D assembly, be it of W2W or D2W type. It is effectively aimed at limiting the thickness of the microelectronics device thus obtained, notably so as to allow it to be integrated into a packaging of an integrated circuit (IC). Furthermore, the planarity of the rear surface of the microelectronics device is particularly critical when there is a plan to continue vertically superposing at least one other device on top of the stack already produced.

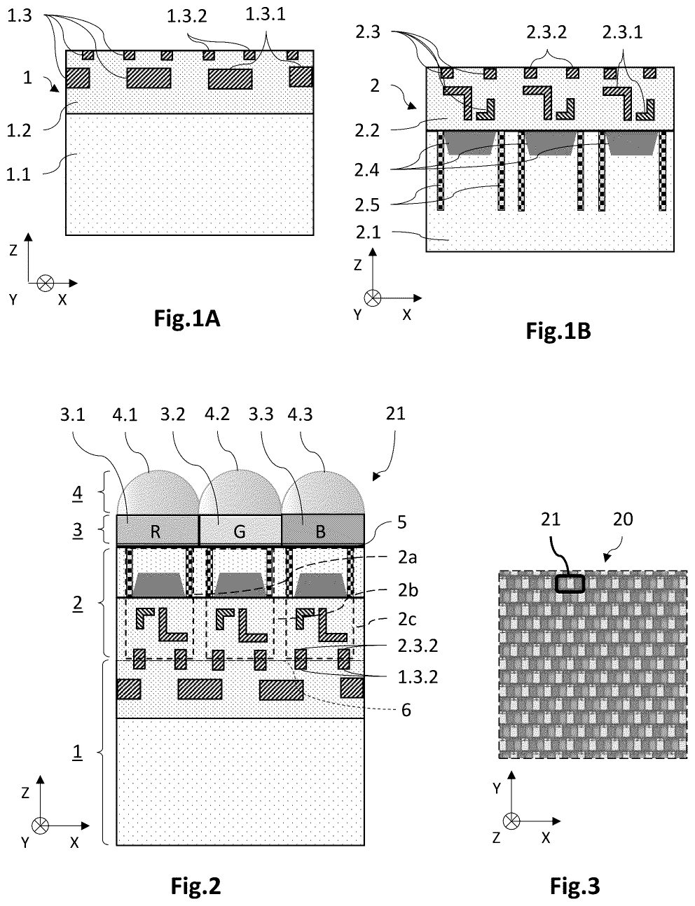

FIG. 1A and FIG. 1B respectively show, in cross section, a portion of a handle wafer 1, and an individual chip 2. The individual chip 2 may be obtained by “dicing” a donor wafer comprising a plurality of identical or similar chips. The chip 2 is suited for being, after being inverted vertically, attached by hybrid bonding to the handle wafer 1.

In the example illustrated in FIG. 1A, the handle wafer 1 comprises a semiconductor substrate 1.1, for example a monocrystalline silicon substrate. The substrate 1.1 is lightly doped, for example by P-type doping. Such doping may be obtained by inserting electron-accepting atoms, such as atoms of boron (B), into the substrate.

A layer 1.2 of insulating material, for example a layer based on silicon dioxide (SiO2), or silica, has been formed on top of the substrate 1.1. This layer may be obtained by thermal oxidation of silicon, at a temperature comprised between 80° and 1200° C., using either steam (wet oxidation) or molecular oxygen (dry oxidation).

Metallic zones 1.3, namely zones made from a metal such as copper (Cu), have been formed in metallization levels of the insulating layer 1.2. The metallic zones 1.3 comprise interconnections 1.3.1 which make the electrical connections necessary for the functioning of the microelectronics devices such as the chip 2 that is intended to be attached to the handle wafer 1 by hybrid bonding. The metallic zones 1.3 also comprise, in the uppermost metallization level (i.e. the one furthest from the substrate 1.1), metallic zones 1.3.2 intended for the hybrid bonding. At least some of the metallic zones 1.3.2 may also contribute to the electrical connections of the attached microelectronics devices. When the metal is copper, the metallic zones 1.3 may be produced using the method known as the “Damascene” method, or its variant, the “Dual-Damascene” method. A person skilled in the art will appreciate that the handle wafer 1 may further incorporate elements other than the aforementioned metallic zones 1.3.1 and 1.3.2, for example active devices such as transistors, or else MEMS or NEMS, etc. In one example, all the devices produced on the handle wafer 1 are produced using traditional CMOS technology.

The chip 2 in the example depicted in FIG. 1B comprises three photosensitive elements to form a colour pixel of an imager. For example, these photosensitive elements are each based on a photodiode. In the case of a BSI-CMOS imager as considered in the present exemplary embodiment of the method, the chips to be attached such as the chip 2 are produced using CMOS technology.

The chip 2 comprises a semiconductor substrate 2.1, for example made of lightly doped monocrystalline silicon, for example having P-type doping achieved by implanting boron atoms.

Three pairwise-adjacent photodiodes 2.4 have been produced beneath the upper surface of the substrate 2.1. The electrical charges (electrons) of photoelectric origin are stored in the photosensitive zone of the photodiode 2.4, referred to as the “read node”, which corresponds to the gate (sometimes referred to as “photogate”) of a CMOS transistor or of a pair of CMOS transistors in the case of a pixel with shared architecture. This may be the case with vertical transfer gate (VTG) CMOS transistor(s). The pixel further comprises transistors for converting the photo-generated charges into a useful electrical signal, notably a follower transistor for reading the electrical charge state of the read node, and a reset transistor for discharging the read node before each fresh acquisition of an image manifested by a buildup of charge of photoelectric origin, as well as possibly also a line selection transistor. These elements may be present in different numbers and be designed and arranged in different ways, depending on the architecture chosen for the pixel: shared two-transistor (2T) architecture, four-transistor (4T) architecture, etc. It is outside of the scope of the present description to describe in detail either the structure or the functioning of such a photodiode.

Each photodiode 2.4 is isolated in a boxlike structure bounded by two deep isolating trenches 2.5 which may be filled with oxide to provide Deep Trench Isolation (or DTI). As a preference, however, the trenches 2.5 may be polarizable deep isolating trenches providing Capacitive Deep Trench Isolation (or CDTI). The trenches 2.5 are then filled, for example, with phosphorus-doped ((P)-doped) polysilicon, for example at a concentration of 1×1019 at/cm³. Passivation of the interface of the deep trenches 2.5, which makes it possible to avoid the dark current, may thus be obtained essentially electrostatically, by polarizing the CDTI trenches during the buildup of electrons in the photodiode 2.4 during image acquisition.

The substrate 2.1 and its microstructures 2.4 are surmounted by a layer 2.2 of insulating material which layer, like the layer 1.2 of the handle wafer 1, may be obtained by thermally oxidizing the silicon.

Metallic zones 2.3, for example made of copper, have been formed in metallization levels of the layer 2.2 of insulating material. The metallic zones 1.3 comprise interconnections 1.3.1 which make the electrical connections necessary for the functioning of the microelectronics devices such as the transistors that control the photodiodes 2.4. The metallic zones 2.3 also comprise, like the metallic zones of the handle wafer 1, metallic zones 2.3.2 intended for hybrid bonding, and which are produced in the uppermost metallization level (i.e. the level furthest from the substrate 2.1). As the person skilled in the art will have appreciated, the metallic zones 2.3.2 of the chip 2 are arranged and suitable for collaborating with the metallic zones 1.3.2 of the handle wafer 1 by coming into contact with one another for the bonding of said chip 2 to said wafer 1. As regards both the functional and structural aspects and the production methods employed, everything stated above with respect to the metallic zones 1.3 of the handle wafer 1 is equally valid for the metallic zones 2.3 of the chip 2, and is not repeated here.

FIG. 2 shows the chip 2 of FIG. 1B, once attached, after having been inverted vertically (namely after the bottom part has become the top part, and, reciprocally, after the top part has become the bottom part), by hybrid bonding to the upper face of the handle wafer 1, namely to the top of said wafer 1. The reference 6 designates the bonding interface between, on the one hand, the upper face of the handle wafer 1 and, on the other hand, the upper (prior to vertical inversion) or rather the newly-lower (following vertical inversion) face of the attached chip 2. The rear substrate of the attached chip 2, the rear face of which faces upwards following the vertical inversion of the chip, has been thinned in order to reduce its thickness from approximately 775 μm to approximately 20 to 30 μm, for example 25 μm. This thinning is performed from above, by thinning the rear substrate.

The photodiodes of the chip 2 are sensitive to the full spectrum of visible light. An array 3 of elementary colour filters may also be integrated on top of the array of an array of chips such as the chip 2, in order to produce a colour digital image sensor, namely so as to allow the imager to capture colour images of a scene. Each photodiode 2.4 is then suitable, in combination with one of said elementary colour filters, for capturing the light corresponding to a respective one of the three primary colours red, green and blue, designated by R, G and B respectively. Thanks to this array 3 of elementary colour filters, each photodiode 2.4 of the image sensor sees just one colour, red, green or blue. To achieve this, each of the photodiodes 2.4 may be surmounted on the upper side, or rear face of the attached chip, by an elementary colour filter corresponding to the primary colour that this photodiode is to detect. In the example depicted in FIG. 3, the array 3 of colour filters thus comprises the filters 3.1, 3.2 and 3.3 for the colours R, G and B respectively, which are each arranged over one of the three photodiodes 2.4 respectively. As a variant, the array 3 of elementary colour filters could be produced as an RGB Bayer filter made up of coloured blocks in the aforementioned primary colours R, G and B, but with two green blocks together with one red block and one blue block (therefore four photosensitive elements) for each pixel.

Furthermore, a network of microlenses 4 may be placed over the top of the array of elementary colour filters 3. More particularly, and still with reference to FIG. 2, each of the elementary colour filters 3.1, 3.2 and 3.3 of the array 3 may be surmounted by a respective microlens 4.1, 4.2 and 4.3, which is suitable for orienting the incident light towards the photosensitive surface of the corresponding photodiode 2.4. For example, the microlenses 4.1, 4.2 and 4.3 are substantially hemispherical.

Finally, a thin insulating layer or a collection of insulating layers is generally provided between the array 3 of colour filters and the upper surface of the photodiodes 2.4, in order to form an antireflection structure 5.

The physical embodiment of the colour filters 3.1, 3.2 and 3.3 as well as the microlenses 4.1, 4.2 and 4.3 and the antireflection structure 5 calls upon methods that are conventional in the creation of imagers. More particularly, because of the precision required, the coloured blocks of the array of filters 3 may be applied directly to the corresponding pixel using a technology similar to the photolithography of the integrated circuits, as may the microlenses of the array of microlenses 4. In order not to overburden the present description, such embodiments will not be described any further.

FIG. 3 shows, in a view from above, a portion of an array of pixels 20 formed of pixels such as the pixel 21 of FIG. 2, surmounted by the array of colour filters 3 from that figure. Here, the pixels are arranged in rows and columns after placement and hybrid bonding on the handle wafer, and form the photosensitive array of a BSI-CMOS imager, in which array each attached chip corresponds to a trichromatic pixel. Imager software recreates the colours of the scene that are captured by the photodiode array, taking the spectral response curves for the colour filters and the antireflection structure 5 into consideration to give a trichromatic RGB end result.

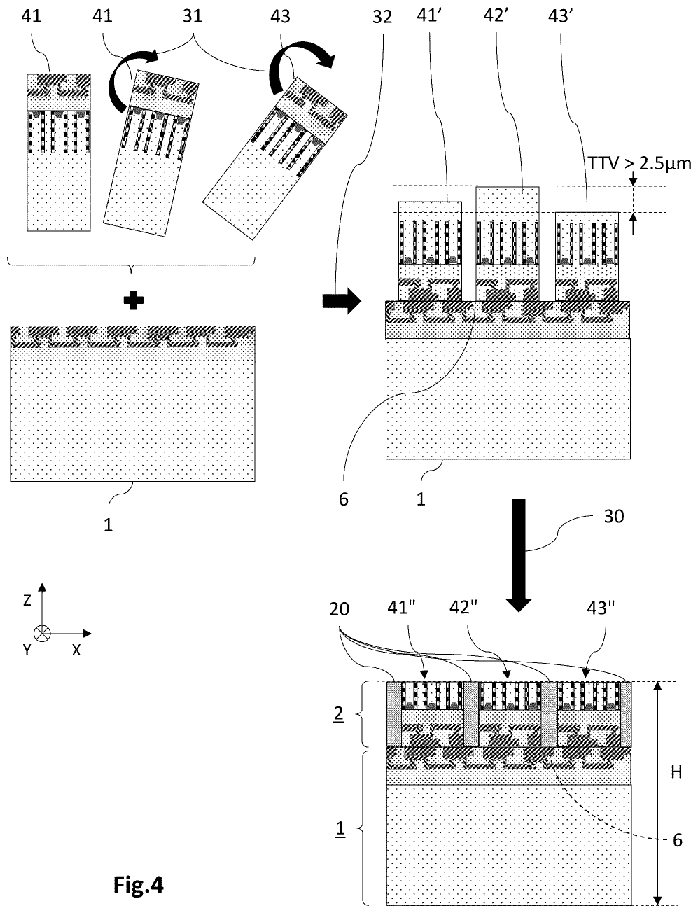

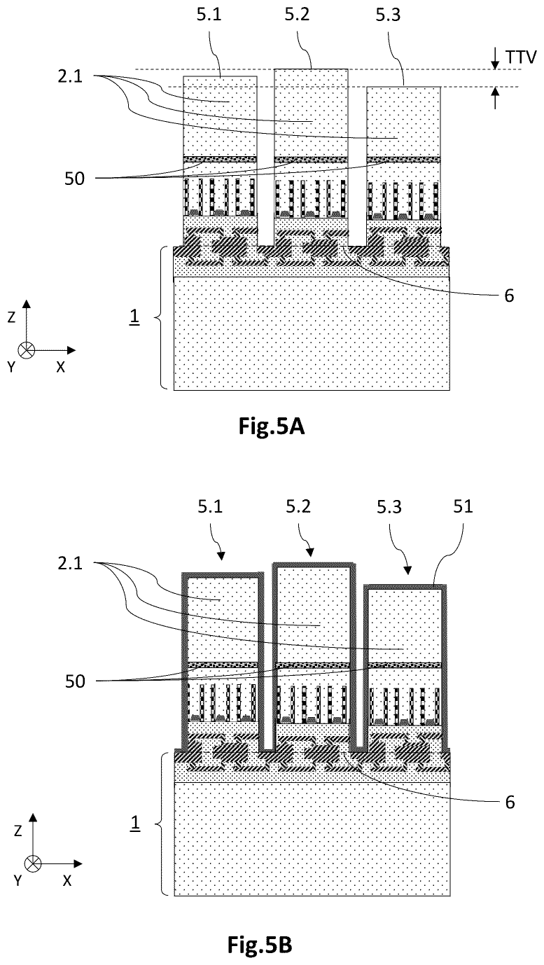

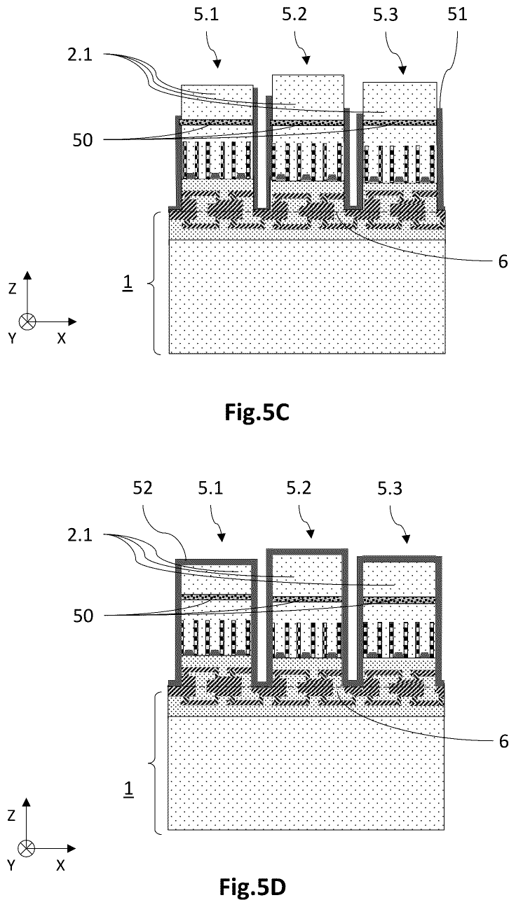

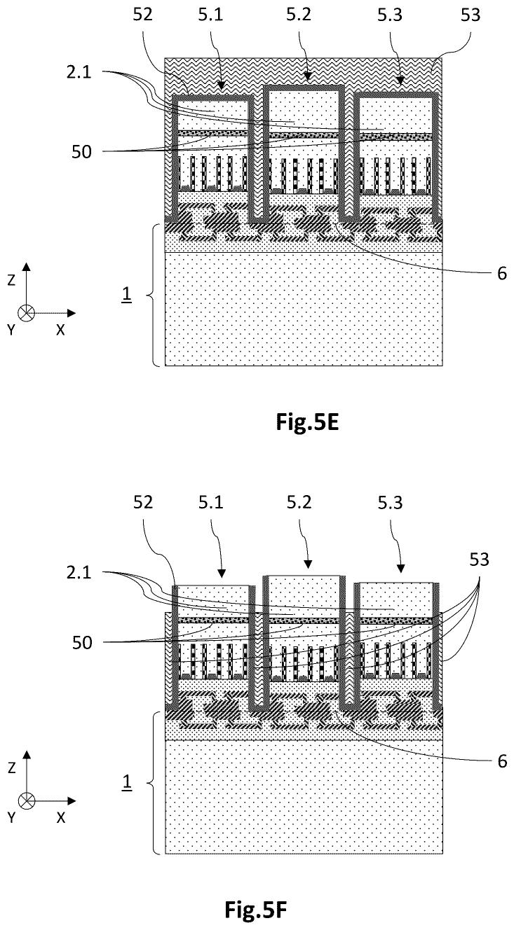

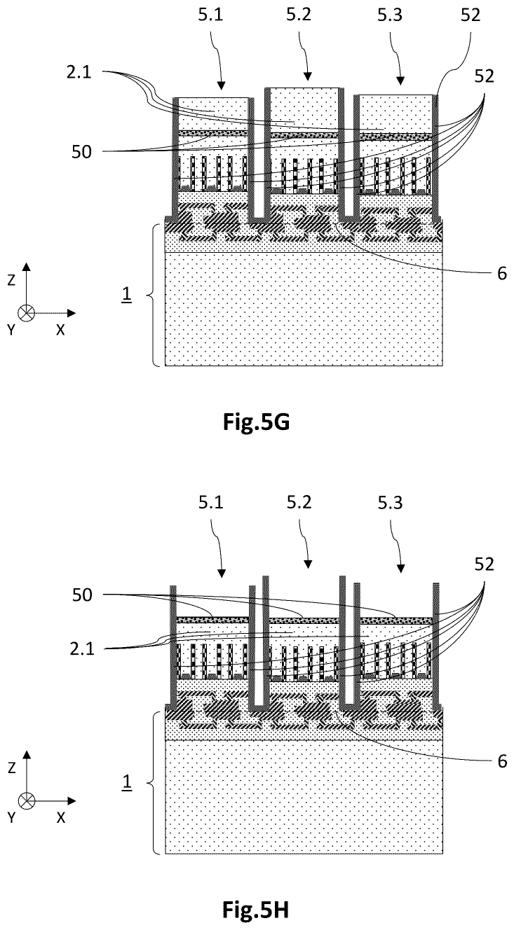

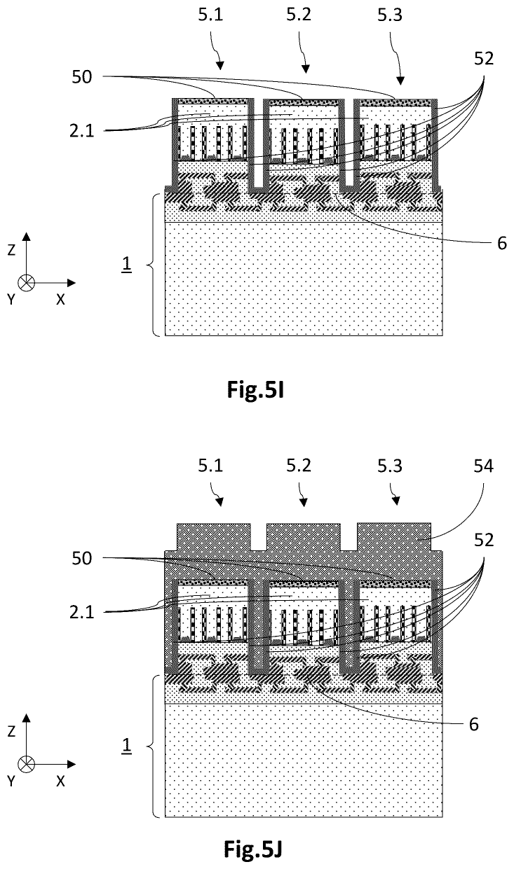

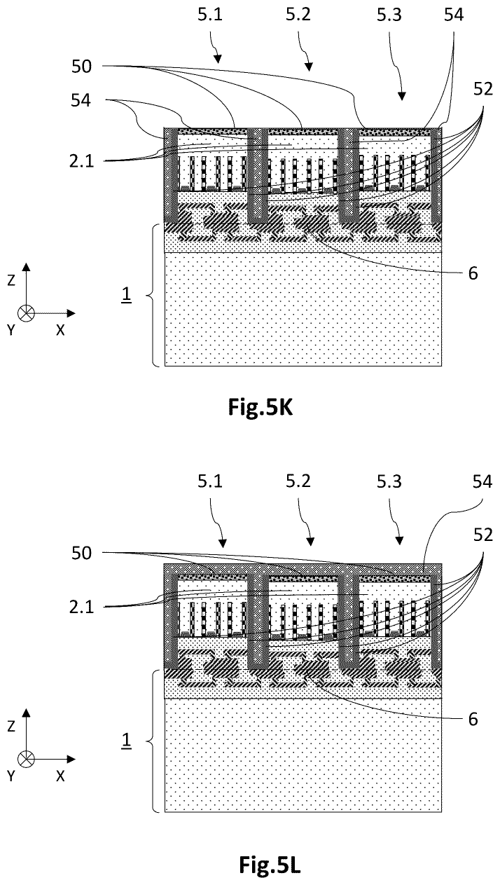

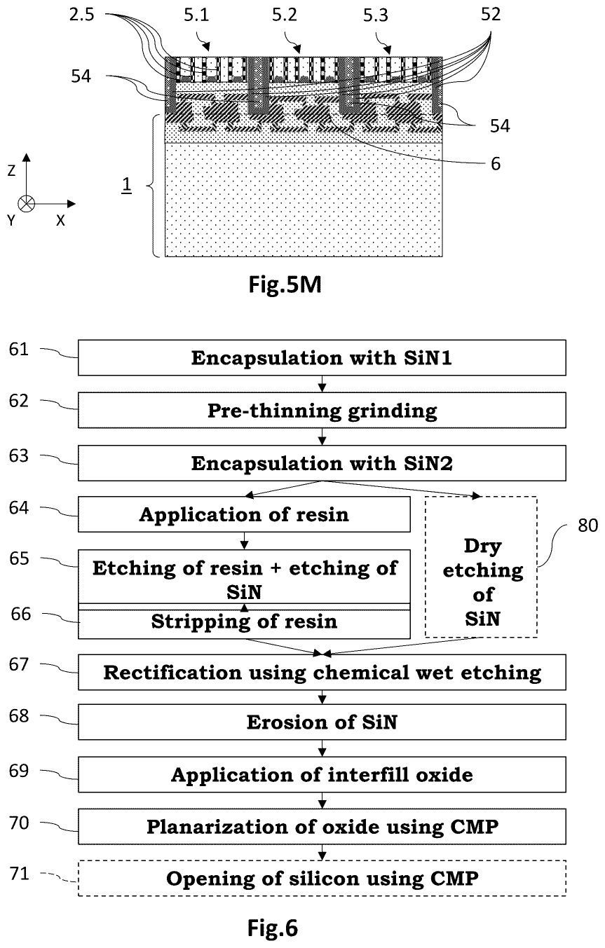

Before going on to describe more specifically one exemplary embodiment of the method for producing a microelectronics device by hybrid bonding of individual chips inverted and bonded on a handle wafer according to the invention, the phase of thinning the rear substrate of the chips thus attached to the handle wafer is put back into context with reference to the schematic diagram of FIG. 4. In that figure, the thinning phase is featured by the “black box” bearing the reference 30, middle right. The handle substrate 1 of FIG. 1A, on the one hand, and, on the other hand a plurality of individual chips 41, 42 and 43 identical or similar to the chip 2 of FIG. 1B are depicted separately in the top left part of FIG. 4.

In FIG. 4, the vertical inversion (turning upside down) of the individual chips 41, 42 and 43, whereby the upper face of a chip prior to inversion becomes the lower face of the chip once inverted, and vice versa, is indicated by the arrows 31. Furthermore, the bonding of the vertically inverted individual chips 41, 42 and 43 onto the handle wafer 1, whereby the respective metallic bonding zones of said chips and of said wafer come into contact with one another, is indicated by the arrow 32.

The figure also shows, top right, the individual chips once they have been inverted and then attached to the handle wafer 1, after this vertical inversion. The individual chips 41, 42 and 43 visible top left, once attached to the handle wafer 1 are referenced in the top right portion of the figure using the references 2.1′, 2.2′ and 2.3′, respectively, in order to distinguish them from the starting individual chips. Once they have been placed on and bonded to the handle wafer 1, the attached chips (including the chips 41′, 42′ and 43′ depicted, together with others) are adjacent to one another in the horizontal plane XY on top of the handle wafer 1 and are spaced apart pairwise, in the direction X and also in the direction Y.

As depicted in the top right portion of FIG. 4, the attached individual chips 41′, 42′ and 43′ do not all have the same height after the thinning of their rear substrate which is performed collectively by grinding, which height may be considered in the vertical direction Z measured from the bonding interface 6 located vertically between the upper face of the handle wafer 1 and the lower face of the attached chips 41′, 42′ and 43′. These differences in height lead to a corresponding variation in the thickness of the microelectronics structure, which may be considered in the vertical direction Z measuring from the rear face of the substrate of the handle wafer 1 (i.e. the lower face of said wafer 1).

A person skilled in the art will appreciate that the thickness of the handle wafer 1 and that of the product wafer 2 are assumed to be constant, given that these two wafers have been ultra-polished prior to the creation of the corresponding devices. The individual chips 41, 42 and 43 diced from their original wafer (i.e. from the “product” wafer or the donor wafer) therefore all have substantially the same thickness, which is approximately 775 μm. For example, the chips exhibit a TTV of less than approximately 1 μm once they have been inverted and bonded to the handle wafer 1. The mean height of the attached chips 41′, 42′ and 43′ after the grinding of their rear substrate is approximately 15 to 25 μm, but these attached and ground down chips exhibit a Total Thickness Variation (or TTV) of at minimum approximately 2.5 μm, or even more. This thickness variation is merely the consequence of thinning the rear substrate of the chips 41, 42 and 43 after said chips have been added to the handle wafer 1, this thinning being performed collectively by grinding the chips after they have been bonded onto the handle wafer 1. In FIG. 4, the TTV is indicated, at the very top right, as the difference between the tallest height and the shortest height, respectively, of the chips attached to the handle wafer 1 and ground, which chips are designated in said figure by the references 41′, 42′ and 43′.

After executing a process flow protocol 30 according to embodiments of the invention (which flow protocol is symbolized by a vertical arrow directed from the top downwards, to the right in FIG. 4), the rear substrate of the attached and ground chips 41′, 42′ and 43′, shown in the top right portion of the figure, has been thinned down so as to reduce the thickness of the attached chips to a height comprised between approximately 15 μm and approximately 25 μm. The monolithic microstructure thus obtained is depicted in the bottom right portion of FIG. 4, to which the arrow 30 is pointing. In this part of the figure, the attached and ground chips, now thinned using the process flow protocol 30, bear the references 41″, 42″ and 43″, respectively. Furthermore, it may be seen in FIG. 4 that the empty spaces between the chips arranged in an XY array on the handle wafer 1 have been filled in with an insulating infill material 20, such as an interfill oxide, to ensure the stability of the pixel array and offer a planar upper surface.

As depicted in the bottom right of FIG. 4, the total height H of the microelectronics structure, here measured in the vertical direction Z from the rear face of the handle wafer 1, is uniform at all points of the upper surface of said microstructure. Stated differently, the respective thicknesses of the rear substrate of the attached and thinned chips 41″, 42″ and 43″ have been equalized by rectifying the upper surface of the attached and ground chips 41′, 42′ and 43′ which are shown in the top right of FIG. 4, this rectification being obtained by planarizing the rear substrate of said chips that have been attached and ground in accordance with the process flow protocol 30 according to the embodiments of the method of the invention.

In summary, and as a person skilled in the art will have appreciated, the process flow protocol symbolically depicted in FIG. 4 by the arrow 30 is what enables the microstructure to make the transition from a state marked by a high TTV, depicted in the top right portion of FIG. 4, to the substantially planar state depicted in the bottom right portion of said figure. Further, this process flow protocol 30 comprises rectification (i.e. imposing uniformity on the height) of the rear substrate 2.1 of the attached individual chips 5.1, 5.2 and 5.3 which are obtained by implementing the method according to the invention.

The sequence of steps which (notably) makes up the process flow protocol 30, together with the advantages afforded by implementing the invention, will now be described with reference to the diagrams of FIG. 5A to FIG. 5M and to the diagram of steps of FIG. 6.

FIG. 5A depicts an example of a microelectronics structure that is similar, in terms of the process steps performed, to the one depicted in the top right portion of FIG. 4. The structural and functional inner workings of the attached individual chips 5.1, 5.2 and 5.3 are identical to what has already been set out above with reference to FIG. 1B for the chip referenced 2 in said figure (prior to the vertical inversion of said chip). Remember that, according to this nonlimiting example, the individual chips comprise three backside illuminated BSI-CMOS photodiodes with capacitive deep trench isolation (CDTI). The total thickness variation (TTV) of the microstructure as may be observed after the grinding, which is performed collectively for all the individual chips 5.1, 5.2 and 5.3 and then their addition by bonding to the handle wafer 1, is also visible and referenced at the top of FIG. 5A.

Furthermore, the attached individual chips 5.1, 5.2 and 5.3 each comprise, in the thickness of their rear substrate, an etch-stop element 50 useful for executing embodiments of the method that enable improved erasure of this TTV, according to the invention. In fact a person skilled in the art will appreciate that the rectification etching that is specific to the embodiments of the invention, and that will be described later on, is selective with respect to such an etch-stop element 50, as will be indicated later. In the example depicted, this etch-stop element 50 is a zone exhibiting a particular type of doping, in comparison with the P-type doping of the substrate of the chips, obtained by the diffusion of atoms at a certain level within the thickness of said substrate. As a variant, it may be an element produced from a specific material, notably in instances in which the substrate is a Silicon-on-Insulator (SOI) substrate.

Whatever the form in which it is embodied, a person skilled in the art will observe that the etch-stop element 50 is located, within the rear substrate of the attached chips 5.1, 5.2 and 5.3, above the photodiodes of said chips once these chips have been vertically inverted before being attached to the substrate of the handle wafer 1. The microstructure as depicted in FIG. 5A is the microstructure after the individual chips 5.1, 5.2 and 5.3 have been added to the handle wafer 1. It is this microstructure that forms the subject of the steps of the thinning and rectification phase of the method of the invention. It is comparable, in terms of the steps of the procedure implemented in order to create it, to the structure depicted top right in FIG. 4, except that the rear substrate 2.1 of the attached individual chips 5.1, 5.2 and 5.3 incorporates, for each chip, an etch-stop element 50 about which more later.

During a first step 61, the result of which is illustrated in FIG. 5B, before anything else, a protection suitable for protecting the deep elements of the microstructure during the pre-thinning grinding of the rear substrate of the attached chips 5.1, 5.2 and 5.3 which will then be performed in the next step 62 is formed. To this end, it is possible in this first step 61 to create a conforming deposit of a protective layer 51 on the upper face of the microstructure of FIG. 5A, namely an encapsulating layer (i.e. a layer that covers in a conforming manner) encapsulating the top of the structure resulting from the adding of the individual chips 5.1, 5.2 and 5.3 to the handle wafer 1.

This step 61 may be implemented in order to encapsulate the attached individual chips 5.1, 5.2 and 5.3 in the protective material of the protective layer 51, and especially the trench-like deep spaces that are formed (as the result of the bonding of individual chips to the handle wafer) between said individual chips, these trenches not being involved in the thinning. This protection prevents the surface of the handle wafer 1, in the zones where the attached chips 5.1, 5.2 and 5.3 are bonded, i.e. in the aforementioned trenches, from being damaged during the grinding of the rear substrate of the attached individual chips 5.1, 5.2 and 5.3. In this particular instance, the bonding zones for the attached individual chips 5.1, 5.2 and 5.3 may actually comprise bare copper which may lie in the bottoms of these trenches. Affording protection using the protective layer 51 also prevents contamination of the surface of the handle wafer 1 which contamination could be caused by the ingress of grinding fluid and/or of debris produced by the grinding. It will be noted that the handle wafer 1 may also be washed throughout the grinding process, for example with deionised water, this likewise contributing to preventing contamination of the microstructure.

In some embodiments, the protective layer 51 may be a layer based on a nitride, for example silicon nitride or Si3N4 (denoted SiN for short). This hard material is able to protect the copper at the bonding interfaces from the various forms of attack liable to cause structural degradation and/or contamination during the grinding and during the chemical wet etching to which processes the microstructure will then be subjected, for the pre-thinning and for the rectification of the rear substrate of the chips, respectively. Such a nitride is preferable to, for example, an oxide such as silicon oxide (SiO2) which would be another option for the protective material, because SiO2 is impervious to the molecules of water (H2O) liable to be present in the grinding fluid and/or to be involved in the context of the implementation of wet etching steps. Other materials, and notably titanium nitride (TiN) and tungsten nitride (WN), as well as various types of oxynitrides, may also be used, as an alternative or in addition to the silicon nitride (SiN).

A protective layer made of good-quality silicon nitride, i.e. of quality compatible with the requirements for use in microelectronics, may for example be obtained by chemical vapour deposition (CVD), for example by low-pressure chemical vapour deposition (LPCVD). Such a method works at a relatively high temperature. As a variant, the silicon nitride layer 51 may be formed by plasma enhanced chemical vapour deposition (PECVD), which works at a relatively lower temperature and under vacuum. The protective encapsulation layer 51 thus obtained is preferably a thin layer: it may, for example, have a thickness of one hundred nanometres (nm) or so.

In a second step 62, the rear substrate of the attached individual chips 5.1, 5.2 and 5.3 is pre-thinned so as to bring its thickness down to a thickness comprised between 20 and 30 μm over the bonding interfaces at which the chips are bonded to the handle wafer, for example of the order of 25 μm. This thinning may be performed by conventional grinding of the rear substrate of the chips, making it possible to remove most of the silicon of this substrate by abrasion, in order to achieve a chip height of approximately 20 to 30 μm. It may therefore be relatively rapid, which is to the benefit of the overall process flow time. It may for example be performed using a diamond-tipped grinding wheel with a binder used as grinding fluid. This makes it possible to eliminate substantial thicknesses of silicon fairly quickly, while at the same time limiting the stresses generated in the silicon. The height of the chips may thus be brought down from approximately 775 μm to approximately 25 μm, with a TTV of the order of approximately 2.5 μm, in the best cases.

The result obtained from this second step 62 is illustrated in FIG. 5C, in which it may be seen that the thickness of the rear substrate of the attached chips 5.1, 5.2 and 5.3 has being substantially thinned in comparison with the microstructure as depicted in FIG. 5A (remember that the drawings are not to scale). As a variant, the pre-thinning could be obtained by implementing a technique known by the name of SmartCut™, which comprises the implantation of ions and a splitting (or separation) anneal, in place of the aforementioned grinding. This technique is widely used for transferring thin crystalline layers from one substrate to another, notably in the context of Silicon-on Insulator (or SOI) technology. Advantageously, the thickness of the layer that can thus be separated from the donor substrate can be determined with great precision by adjusting the energy used for the implantation of light ions (for example hydrogen ions (H+) or helium ions (He+), and therefore the depth of the rupture zone thus buried. The thermal anneal (at between approximately 350° C. and approximately 600° C.) then causes the buried cracks to spread until the silicon splits and the upper portion of the rear substrate of the attached chips thus separates away, thereby achieving the pre-thinning. In the context of the invention, this SmartCut™ technique allows good control over the amount of pre-thinning thus achieved, namely over the thickness of the upper portion of the rear substrate of the chips that is removed by this means.

A person skilled in the art will appreciate that, with this pre-thinning step 62, there is no attempt to eliminate the TTV using a CMP-type process aimed at obtaining high-quality planarity of the rear surface of the substrate (i.e. a planarity of the order of a few nanometres). This distinguishes the invention from the CMP-based thinning methods that a person skilled in the art might necessarily consider to be the only appropriate methods, given the great thickness of silicon to be removed, which would naturally direct this person towards a chemical mechanical method. Indeed, the person skilled in the art would consider a combination of several CMP operations, performed with different parameters and/or different tools, and possibly interspersed with steps of repairing and/or of protecting the microstructure, in an attempt to obtain satisfactory planarity using a CMP type of polishing.

This is also the reason why, in the context of the present invention, the step 62 of the method is referred to as a “pre-thinning”. Specifically, the result obtained at the end of this step 62 lies essentially in a thinning that is relatively extensive and quick, but also relatively imperfect in terms of planarity. Furthermore, according to the invention, the grinding makes a first attack on the rear substrate of the chips enabling only a substantial thinning of the thickness of the rear substrate of the attached individual chips 5.1, 5.2 and 5.3, which thickness is not definitive. It will then be followed by an additional attack that achieves additional thinning, relatively less quickly but relatively far more finely, namely that is more effective in terms of the planarization of the surface being worked. This is the step 67 of the method illustrated by FIG. 6, which will be explained later. As will become apparent from the description that follows, this other thinning step 67 is performed, after the step 62, preferably chemically and more particularly using chemical wet etching. This step 67 enables the respective levels of the upper surface of the rear structure of the attached individual chips 5.1, 5.2 and 5.3 to be made uniform, namely enables the upper surface of the microstructure to be planarized so as to erase the TTV introduced by the grinding, thereby where applicable allowing 3D integration to be continued, without bonding defects, to stack further devices on top of this surface.

As indicated symbolically in FIG. 5C, the protective layer 51 emerges from the pre-thinning grinding step 62 damaged. It may even have practically disappeared from the upper portions of the sidewalls of the trenches that extend vertically between the attached individual chips 5.1, 5.2 and 5.3, near the upper surface of the microstructure. If the silicon nitride protective layer 51 is too damaged, i.e. is no longer intact enough, there is a risk that it will not be sufficiently resistive to the subsequent chemical attacks that are envisioned for erasing the TTV in accordance with embodiments of the invention.

This is why, in a third step 63, the result of which is illustrated in FIG. 5D, and before continuing with the operations that need to be carried out in order to make the height of the rear substrate of the attached individual chips 5.1, 5.2 and 5.3 uniform, provision may be made to form a further protection of the microstructure, i.e. an additional protection to that afforded by what remains of the layer 51. This may be achieved by, for example, depositing a conforming second protective layer 52. In some embodiments, this new protective layer 52 once again encapsulates the entire microstructure. It is able to repair or supplement the first protective layer 51, which had been deposited earlier in step 61, but which may have been damaged by the pre-thinning grinding that was applied, in step 62, to the rear substrate of the attached individual chips 5.1, 5.2 and 5.3.

In some embodiments, the second protective layer 52 may be a layer based on a nitride of the same kind as the nitride of the first protective layer 51 produced in step 61. As a preference, the nitride of the second protective layer 52 is then likewise silicon nitride (SiN) when the nitride of the first protective layer 51 is itself silicon nitride (SiN). Statements made above in connection with the first protective layer 51, regarding its features, how it is produced and the variants that may be considered, also apply and are equally valid in respect of the second protective layer 52, and are therefore not repeated here.

A person skilled in the art will appreciate that implementation of this step 63 of forming a second protective layer 52 is notably dependent on the original quality of the first protective layer 51, and on the extent to which said layer 51 has potentially been damaged by the pre-thinning grinding step 62. The greater the extent to which the protection afforded by the first protective layer 51 has been reduced at the end of this grinding operation, the more important it is to produce the second protective layer 52.

The method continues with the removal of the second protective layer 52 only at the planar portions of the rear substrate 2.1 of the attached individual chips 5.1, 5.2, 5.3 in order to selectively uncover the rear substrate 2.1 of said chips so that these can undergo the chemical wet rectification etching. This removal is achieved by etching through a mask obtained beforehand by photolithography of a layer of photosensitive resin. More particularly, the following method steps seek to uncover the silicon of the rear substrate 2.1 of the attached individual chips 5.1, 5.2 and 5.3 at the horizontal upper surface of said chips, so as to be able to equalize their height by chemical wet etching according to the embodiments of the invention. To this end, the silicon nitride (SiN) of the second protective layer 52 is removed only at the planar portions of said layer 52 which form a capping at the upper part of the rear substrate of the attached chips 5.1, 5.2 and 5.3.

In a fourth step 64, the result of which is illustrated in FIG. 5E, a layer 53 of standard commercially-available (positive-tone or negative-tone) photosensitive resin is initially applied so that photolithography can be used to create a mask useful for uncovering only the zones relevant to the forthcoming chemical etching, namely the upper surfaces of the rear substrate of the attached individual chips 5.1, 5.2 and 5.3.

This resin, or resist, is for example a resin that is relatively thick and viscous, so as to exhibit good coverage. Specifically, there are dips and bumps on the surface that is to be covered, because of the topology of the surface of the microstructure which is marked by the TTV that it is sought to eliminate. The thickness of the resin layer 53 is for example of the order of 25 μm. It may be deposited by spin coating, or by any other available equivalent method.

For example, the resin may be the resin known by the trade name AZ® 3DT-102M-15™, available from the company MicroChemicals™. This is a resin with a high aspect ratio. As a variant, it may also be the resin known by the trade name PMER P-BZ4000™, available from the company TOK™.

In a fifth step 65, the result of which is illustrated in FIG. 5F, a dry etching, which is therefore highly anisotropic, is performed on the resin layer 53 and on the nitride of the underlying protective layer 52, on the top of the attached chips 5.1, 5.2 and 5.3. This allows the monocrystalline silicon 2.1 of the rear substrate 2.1 of said chips to be uncovered, at the upper surface of the microstructure, without damaging the rest of the microstructure. The etching may be a plasma etching, which is to say a physical etching. It may also be a chemical dry etching such as a Reactive-Ion Etching better known by its acronym RIE.

Because of their anisotropic nature, these etchings attack essentially the top of the chips 5.1, 5.2 and 5.3, and to a far lesser extent the inter-chip zone which is better protected by the resin layer 53. Stated differently, the silicon nitride (SiN) zones between the vertical flanks of the protective layer 52 are protected by the resin layer 53. That means that the SiN of the protective layer 52 can be removed only on the rear face of the chips 5.1, 5.2 and 5.3.

In a variant, the resin of the layer 53 and the SiN capping of the protective layer 52 may also be removed, at the rear face of the chips 5.1, 5.2 and 5.3 only, by chemical mechanical polishing (CMP). At the end of this step of dry etching of the nitride layer 52, and as indicated in FIG. 5F, the silicon 2.1 of the rear substrate of the attached chips 5.1, 5.2 and 5.3 is uncovered, at the top of the microstructure. The vertical portions of the protective layer 52 have been unaffected, or else affected very little, by the aforementioned etching, even if the resin mask 53 has been damaged in its upper parts, as symbolically illustrated in the figure. In any event, the nitride of the protective layer 52 remains present, and intact, in the bottom of the trenches between the attached individual chips 5.1, 5.2 and 5.3 near the bonding interface 6, because at these points it has been protected by the mask formed by the resin layer 53.

It will be appreciated that, after the above selective etching, the nitride of the protective layer 52 may be covered at the bonding interface 6 by etching residues and at that point is covered, at least partly, by what remains of the resin mask 53 after the photolithography and the etching.

It is therefore necessary to remove the residues of the resin mask 53 that are present in the bottom of the trenches, i.e. in the bottom of the trench-shaped spaces that exist between the attached individual chips 5.1, 5.2 and 5.3. This is the purpose of a sixth step 66 of the procedure, that yields the microstructure according to FIG. 5G. In this microstructure:
the upper face of the attached individual chips 5.1, 5.2 and 5.3 exposes the silicon of the rear substrate 2.1 of said chips; and
the trenches between these chips are covered and therefore protected by the silicon nitride of the protective layer 52.

In order to do this, there are a number of methods that can be used for removing, or stripping, the resin, notably plasma stripping and/or wet stripping.

In some embodiments, the residual portions of the resin mask 53 can be removed by wet etching, which has the advantage of being isotropic. This type of wet etching is purely chemical, the material corresponding to the resin being modified at its surface by an attacking solution, and this part then being dissolved by a solvent. Repeating the alternating steps of chemical attack and chemical dissolution progressively eats away the photolithography resin. The quantity of resin removed in each iteration is governed by the duration of contact between the resin and the acid attack solution.

The resin may be brought into contact with the attacking solution either by immersing the wafer in a chemical bath or by spraying the solution directly onto the wafer. These may be aqueous alkali solutions such as KOH or NaOH, for example 2% or 3% solutions.

The solvent may be NMP (1-methyl-2-pyrrolidone), which because of its very low vapour pressure is suitable for removing layers of photosensitive resin. This then allows it to be heated to 80° C. so that particularly well cross-linked films of photosensitive resin can be removed. Another example of a solvent suitable for removing the layers of photosensitive resin is DMSO (dimethyl sulfoxide) heated to 60-80° C. This solvent displays good performance as a stripper of photosensitive resin.

In certain embodiments, the two above-mentioned methods may be combined: plasma stripping (dry etching) then allows the resin to be removed while wet cleaning performed afterwards makes it possible, where applicable, to remove any remaining residues.

In a variant of the embodiment of the steps 64, 65 and 66 that were described hereinabove, it is possible to perform anisotropic dry etching of the protective layer 52 of silicon nitride (SiN), making it possible, because of the difference in thickness of said layer 52 between the top of the chips and the inter-chip zone, to remove the SiN only at the top of the chips 5.1; 5.2 and 5.3, namely on the rear face of said chips. In the step diagram of FIG. 6, this variant is illustrated by a branch representing an alternative to the blocks 64, 65 and 66, and bearing the reference 80. With this variant the structure depicted in FIG. 5D transitions directly to that depicted in FIG. 5G. Stated differently, the intermediate states illustrated by FIG. 5E and FIG. 5F are not encountered in the implementation of the method according to this variant.

In a seventh step 67, the rear substrate of the attached individual chips 5.1, 5.2 and 5.3 is chemically etched, for example by chemical wet etching. The purpose of this chemical etching, according to the invention, is to bring the level of the rear substrate 2.1 of each of said chips down to the same height on the handle substrate 1, as shown in FIG. 5H. Specifically, it will be recalled that, according to the embodiments of the invention, this planarization is not intended to be achieved using CMP processes as suggested by the prior art, but consigned to the chemical etching step 67 considered here. The purpose of this etching is therefore referred to here as being rectification etching. It will be appreciated that recourse to a chemical wet etching step in order to achieve the expected rectification is somewhat counterintuitive in that a person skilled in the art knows that chemical wet etching is highly isotropic, and that using it is liable to damage elements at the bonding interfaces 6 between, on the one hand, each of the attached individual chips 5.1, 5.2 and 5.3 and, on the other hand, the top of the handle wafer 1, such as copper tracks or studs that have been produced at this interface. As will be seen again later on, it is the purpose of the protective layer 52 to protect the bottom of the trenches between the attached individual chips 5.1, 5.2 and 5.3 during the chemical wet etching that achieves the rectification of the rear substrate 2.1 of said chips.

The rectification etching 67 employed is etching that is selective with respect to the etch-stop element 50 comprised in the rear substrate 2.1 of each of the attached individual chips 5.1, 5.2 and 5.3. For example, when the etch-stop elements 50 are zones having a P-type doping that is different from the standard P-type doping of the silicon substrate 2.1 of the attached individual chips, the parameters of the rectification etching are such that this etching is selective with respect to said different P-type doping of the etch-stop zones 50. Stated differently, the rectification etching acts against the normally-doped substrate 2.1 but has no effect on the differently-doped silicon zones 50 contained within said substrate. The consequence of this is that the rear substrate 2.1 of each of the attached individual chips 5.1, 5.2 and 5.3, which is exposed to the rectification etching, is removed from the top down, until the level of the etch-stop elements 50 is reached. Because the level (in the heightwise direction, i.e. in the vertical direction Z) of the etch-stop elements 50 is, by design, the same for all of the attached individual chips 5.1, 5.2 and 5.3, the result is that the height of said chips after the etching has stopped as a result of these etch-stop elements being encountered is the same for all the chips. Stated differently, the thickness of the rear substrate 2.1 of each of the attached chips 5.1, 5.2 and 5.3 is now uniform over its entire surface, as shown in FIG. 5H.

In some embodiments, the rectification etching may be chemical wet etching. Such etching may be performed using an acid solution. For a substrate made of silicon, this may for example be an acid solution based on hydrofluoric acid (HF) or on nitric acid (HNO3). These acids are capable of reacting with the silicon dioxide layer that naturally forms at the surface of the silicon of the rear substrate 2.1 of the attached individual chips 5.1, 5.2 and 5.3. For a substrate 2.1 made of gallium arsenide (GaAs), preference is given to an acid solution based on hydrochloric acid (HCl), given that chlorine ions react very strongly with gallium. As a variant or in addition, it is also possible to use a solution based on a weak acid, such as citric acid diluted in water, for example a 50 vol % solution (C6H8O7:H2O, 1:1), and/or hydrogen peroxide (peroxide of hydrogen—H2O2) diluted in water (H2O).

The effects, detrimental to the integrity of the microelectronic structure, of the highly isotropic nature of such chemical wet etching are prevented by the first protective layer 51 supplemented, where applicable (and as depicted), by the second protective layer 52, this layer (or these layers) being, in the example considered here, made of silicon nitride (SiN) or from another type of nitride with comparable properties. This is because silicon nitride (for example Si3N4) is not attacked by wet etching of the above-mentioned type.

One advantage of wet etching over dry etching (physical or plasma or even ion bombardment etching) is the possibility of planning for the etching to be selective. According to the invention, this selectivity is exploited in order to define etch-stop elements that stopped the etching of the rear substrate of the individual chips 5.1, 5.2 and 5.3 which have been attached to the handle substrate 1, in order to achieve the desired uniformity of the height of the rear substrate of said chips.

In practice, there are a number of conceivable ways in which such etching can be implemented in order to obtain selectivity of the chemical wet etching with respect to the etch-stop elements 50.

First of all, and as was explained above, the rear substrate 2.1 of the chips 5.1, 5.2 and 5.3 may comprise etch-stop zones 50 having a specific doping, formed prior to the creation of the chips at a determined depth in the rear substrate of the wafer (or wafers) referred to as “product” wafer(s) in which the chips have been produced. Once the chips have been singularized by dicing them from their product wafer, then tested, and then inverted and bonded to the handle substrate 1, the respective zones 50 of the attached individual chips are situated at a height that is determined, and identical, for each of these chips. This is especially true if the chips thus attached have come from the same donor substrate, which is to say if they have been previously diced from the one same single product wafer. This doping zone 50 in the rear substrate of the chips is a zone that has a doping that differs from the doping of the monocrystalline silicon of the substrate 2.1, which doping may for example be a standard P-doping. The doping of the etch-stop zones 50 may also be a P-type doping, but with a lower concentration of electron accepting atoms. The detection of the zones 50 may then cause the chemical wet etching to stop, and do so at a level (i.e. at a height) that is the same for all the chips. This then introduces the effect of selectivity into the etching that achieves the desired rectification of the height of the rear substrate of the respective attached chips.

As a variant, it is possible to plan for the etching to be stopped on detection of a different material in the substrate, for example gallium arsenide (GaAs) or aluminium (Al), if the rear substrate 2.1 of the attached individual chips 5.1, 5.2 and 5.3 is a composite substrate. Stated differently, the etch-stop elements 50 may be elements made from a specific material which have been produced in the rear substrate 2.1 of the attached individual chips 5.1, 5.2 and 5.3 prior to the formation of the devices forming said chips, and notably CMOS technology photosensitive devices produced on this substrate 2.1.

As a further variant, and notably but not solely in the event that the rear substrate 2.1 of the attached individual chips 5.1, 5.2 and 5.3 is an epitaxial silicon substrate a few micrometres (μm) thick, a dedicated thin layer may be provided by way of rectification etching etch-stop element. This may be a layer produced in the substrate 2.1 from a specific material, such as a thin layer of silicon oxide (SiO2) or a thin layer of silicon nitride (for example Si₃N₄). As is well known to those skilled in the art, in the context of epitaxial substrates, a “thin layer” means a layer of which the thickness may be comprised between a few nanometres and a few tens of nanometres, for example between 5 to 8 nm at the lower limit, and 50 to 80 nm at the upper limit.

Finally, the etch-stop element 50 that stops the rectification etching may also be a buried etch-stop layer, such as a Buried Oxide, or BOX, layer in instances in which the rear substrate 2.1 of the attached individual chips 5.1, 5.2 and 5.3 is a Silicon-on-Insulator, or SOI, substrate.

However the etch-stop elements 50 for stopping the rectification etching are embodied, the chemical etching that is performed is selective with respect to the etch-stop elements 50, and allows satisfactory rectification of the surface of the rear substrate of the attached individual chips 5.1, 5.2 and 5.3.

The rectification etching of this step 67 makes it possible, as a supplement to the pre-thinning grinding step 62 performed using CMP, not only to complete the thinning so as to bring the level of the rear substrate of each of the chips of the microstructure down to the height determined by the level of the etch-stop elements 50, but also and especially to obtain good uniformity of said levels, for example with a TTV reduced to a value of the order of ±5 nm. The main purpose of the rectification etching step is therefore to erase the TTV introduced as a result of the CMP pre-thinning grinding step and which was at least approximately 2.5 μm.

A person skilled in the art will appreciate that, during the course of the chemical wet etching step 67 in the above rectification step, and the highly isotropic nature of such etching notwithstanding, the second protective layer 52 of silicon nitride (SiN) resists. It therefore performs its function which is to protect the bottom of the trenches between the attached individual chips 5.1, 5.2 and 5.3. Indeed, that is where there are elements that need to be protected because their intactness needs to be preserved, such as the metallizations produced at the bonding interfaces 6 between, on the one hand, each of the attached individual chips 5.1, 5.2 and 5.3 and, on the other hand, the top of the handle wafer 1. In particular, there are, at this interface 6, copper tracks or studs that must not be attacked.

A person skilled in the art will appreciate that, in variants, other selective thinning techniques may be employed, in place of the chemical wet etching. For example, thinning by chemical mechanical polishing (CMP) may be performed after the pre-thinning grinding, with stopping at a doped or implanted layer that acts as a CMP stop element 50.

In an eighth step 68, the silicon nitride portions corresponding to the vertical flanks of the protective layer 52 which project upwards from the silicon of the stop elements 50 are eroded away. These portions were left intact by the chemical attacks made on the microstructure during the chemical wet etching step 67 explained above. They form spine-like projections pointing upwards from the level of the stop elements 50, as is visible in FIG. 5H. Once these spines have been eroded away by implementation of this eighth step 68, the structure as shown in FIG. 5I is obtained.

This step 68 may be performed by polishing of CMP type. In practice, the polishing times are very short and determined as a result of experimentation alone. Specifically, silicon nitride is very quickly opened up under the effect of CMP. Moreover, there are no means of automatically detecting that the level of the silicon of the rear substrate of the attached individual chips 5.1, 5.2 and 5.3 has been reached.

At the end of this step 68, and as shown in FIG. 5I, the upper level of the attached individual chips 5.1, 5.2 and 5.3 has been rectified, which is to say that the level of the rear substrate of the attached individual chips 5.1, 5.2 and 5.3 has been rendered uniform, to within a few nanometres, for example to within ±5 nm. The upper surface of the microstructure is nevertheless still not exactly planar, given that the trenches between said chips still remain.

The steps that follow seek to fill in these trenches (step 69) and then polish (step 70) the top of the microstructure, in order to obtain a microstructure upper surface that is indeed planar.

In a ninth step 69, a layer 54 of dielectric material is formed to interfill the spaces between the attached individual chips 5.1, 5.2 and 5.3. The thickness of the interfill layer 54 is comprised, for example, between approximately 20 μm and approximately 25 μm. The interfill material is, for example, a thick oxide. This step 69 allows the free spaces between said chips to be filled down to the bottom of the trenches that separate these chips, as shown in FIG. 5J which illustrates the microstructure after the layer 54 of interfill oxide has been created. Stated differently, the oxide layer 54 is able to fill the irregularities and roughnesses present on the upper surface of the microstructure.

A person skilled in the art will appreciate that, according to the invention, the filling of the trenches between the attached individual chips 5.1, 5.2 and 5.3 is advantageously performed only at the end of the flow protocol, namely once the rear substrate of said chips has been thinned and the upper surface of the microstructure has then been planarized. In that way, the interfill oxide is unaffected by the operations of CMP thinning (step 62) and of chemical wet rectification etching (step 67) of the rear substrate, which have preceded its creation. The interfill oxide therefore does not need to be repaired or supplemented as a result of the thinning and rectification performed.

In order to create the interfill oxide layer 54, it is possible for example to create a “whole wafer” oxide layer, for example of silicon dioxide (SiO2) which is the dielectric material most commonly used in the processing of semiconductor devices.

Application may be by chemical deposition, such as for example Plasma Enhanced Chemical Vapour Deposition (PECVD), of tetraethylortho silicate (TEOS) by way of precursor of silicon dioxide (SiO2), followed by simple hydrolysis, producing SiO2 by releasing ethanol (CH3CH2OH). Such application is a conforming deposition method, which is to say that the interfill oxide layer 54 deposited perfectly follows the relief of the microstructure that it covers. Advantageously, the relatively moderate temperature at which PECVD deposition is performed is compatible with the requirements of the materials of the components of the device. Specifically, the chemical reaction of decomposition of the precursor gases, which reaction forms the start of the deposition, is assisted by a radiofrequency electric discharge (at 13.56 MHz) which ionises the gases and forms a plasma (namely an overall-neutral mixture made up of ions and of electrons). That enables the deposition to be performed with the device kept at a temperature below approximately 500° C., whereas with a conventional low-pressure CVD method, the decomposition of the precursor gases is obtained by applying relatively higher temperatures (typically of the order of approximately 1000° C.). As a variant, deposition may also be performed using a physical method, such as cathodic sputtering, or spin-off methods achieving deposition through a centrifugal effect.

As may be seen in FIG. 5J, this deposition creates a topography at the upper surface of the device, which topography follows the relief corresponding to the upper ends of the attached individual chips 5.1, 5.2 and 5.3 on the handle wafer 1.

In a tenth step 70, the oxide layer undergoes chemical mechanical polishing (CMP), thereby planarizing (which is to say levelling) the surface through the combined action of chemical and mechanical forces. This step 70 makes it possible to make good the topography brought about by the deposition of the oxide layer 54, performed in the preceding step 69, so as to establish the planarity of the upper surface of the microstructure. The polishing may be stopped in two different ways, the two embodiments for which are described below.

In a first embodiment, the result of which is illustrated in FIG. 5K, the removal of the oxide of the layer 54 by CMP may be stopped upon detection of the stop elements 50 made of silicon or of oxide, which have already been used as etch-stop elements in the chemical wet rectification etching performed in the seventh step 67 described earlier. More particularly, the chemical mechanical polishing may be stopped upon detection of an increase in torque of the polishing machine resulting from the change in friction upon contact with the stop elements. This embodiment is better suited to performing the eleventh and final step with a view to creating an imager (see later).

In another, alternative, embodiment, the polishing may be stopped after a determined length of time and/or at the command of end-of-travel sensors (or endpoints) provided in the polishing machine. This embodiment allows polishing to be stopped at a level situated within the oxide layer 54, as shown in FIG. 5L. This embodiment provides the possibility of performing further D2W-type or W2W-type bonding operations on top of the microstructure, so as to stack further chips still on the same handle substrate 1. Specifically, further metallic tracks and/or further bonding metallic studs, such as the tracks 1.3.1 and the studs 1.3.2 of the handle substrate 1 of FIG. 1A may be formed, within the oxide layer 54 itself, using a method of the Damascene or Dual-Damascene type.

A person skilled in the art will appreciate that, whatever the embodiment selected for step 70, the polishing of the oxide layer 54 yields a good result, i.e. satisfactory planarity of the surface of the microstructure after polishing, because the rear substrates of the attached individual chips 5.1, 5.2 and 5.3 have been brought down to the same height by virtue of the earlier steps of the method. Specifically, the CMP polishing performed in this tenth step creates little by way of step change at the trenches separating said chips 5.1, 5.2 and 5.3, unlike polishing steps performed directly and solely for the purpose of thinning the thickness of the rear substrate of these attached chips and rendering this thickness uniform. There is therefore no need to re-form either the silicon nitride of the layer 52 or the silicon oxide of the layer 54.

Stated differently, what is obtained is a microstructure that presents itself as a monolithic entity with an upper surface that is properly planar, with a TTV reduced to just ±5 nm.

When the chips are, as in the nonlimiting example considered in the present description, vertical transfer gate (VTG) photodiodes with capacitive deep trench isolation (CDTI) for creating an imager of BSI-CMOS type, the method may comprise an eleventh and final step 71, which is a polishing step, the result of which is shown in FIG. 5M. This polishing may be performed using chemical mechanical polishing (CMP).

This is not selective with respect to the material of the stop elements 50 (i.e. not selective with respect to P-doped silicon in the example in which these elements are zones of the rear substrate 2.1 of the chips 5.1, 5.2 and 5.3 which are produced with such doping), and neither is it selective with respect to the material of the protective layer 52 (i.e. not selective with respect to silicon nitride in the exemplary embodiment of steps 61 and 63 given here). It thus enables the rear ends of the capacitive deep trench isolation trenches 2.5 of the attached individual chips 5.1, 5.2 and 5.3 to be uncovered in a single step, which is to say allows them to be exposed on the side of the upper face of the microstructure. It will be noted that the microstructure obtained corresponds to a microstructure that is identical, in terms of the process flow operations performed, to that depicted in the bottom right portion of FIG. 4, which corresponds to the photosensitive device of just a single pixel, whereas FIG. 5M shows three such devices, suitable for creating a trichromatic RGB pixel.

As a person skilled in the art will have appreciated, this step 71 is specific to the creation of an imager. Opening the oxide insulation until the upper ends of the capacitive deep trench isolation trenches of the photodiodes are uncovered effectively makes it possible (through the agency of one (or more) suitable metallization layer(s) to be created for that purpose) to polarize the capacitive trenches 2.5 in order to render the photosensitive devices operational. Without that, the imager that is the example of an application of the method considered in the present description would not function. Nevertheless, it must be remembered that the invention is not restricted to that example, but applies to the phase of thinning of all types of individual chips that have been inverted and attached by bonding to a handle substrate.

More generally, the invention is not restricted to the particular embodiments described hereinabove. Different variants and modifications will be apparent to those skilled in the art. The invention extends to all the embodiments covered by the claims.

It is thus specified that, in the context of the present invention, the term “chip” extends to any microelectronics element intended to be transferred onto a device, particularly onto a support larger in size than the chip. These chips may or may not be processed, or else may be made on the basis of silicon or on the basis of other materials such as InP, for example, or else also may be made of GaAs, of silicon carbide (SiC), of silica, of germanium (Ge) or of sapphire and may have surface layers of materials such as silica, silicon nitride (SiN), of metals such as copper (Cu) or titanium (Ti), and any other layers of materials known in the field of microelectronics (HfO2, SiOC, AlN, Al2O3, GaN, etc.).

Typically, the chips may contain integrated circuits, which may be connected to the outside by means of electrical interconnection parts. These interconnections may be produced directly at the bonding interface. These electrical-connection parts may have dimensions smaller than 5 μm, which entails a very high level of precision in the placement of the chips, for example of the order of one micrometre.

The chips may undergo processing operations prior to the transfer proposed here, but may also undergo later processing operations. Such processing operations may comprise, non-exclusively, the integration of circuits, the creation of vias, and/or the creation of any additional active or passive component(s). For example, the chip transfer may be performed on chips that have not yet been completely formed and that possibly still simply consist of a single block of homogeneous material intended to be transformed later.

However, as a preference, the chips that are to be transferred are functional devices that have advantageously been triaged beforehand by subjecting them to an electrical test so that any non-functional chips have been eliminated, where applicable. What has been transferred onto the destination substrate (“handle” substrate) is therefore only chips of which the functional status has been verified. This reduces or even eliminates the risk of the entirety of the device that is in the process of being manufactured, namely the imager in this example, being rendered non-functional as a result of an arbitrary individual chip, namely any one of the photodiodes 41, 42, and 43 in the example, being non-functional.

A person skilled in the art will further appreciate that the method may be implemented simultaneously on a plurality of individual chips that have been transferred onto the handle wafer 1.

It also goes without saying that, although the chips have been singularized, they can be attached to the handle wafer 1 in batches, rather than separately one-by-one by a pick and place tool, so as to save time.

1. A method for producing a microelectronics device, involving hybrid bonding of a plurality of individual chips which are inverted vertically and then attached by bonding to a semiconductor wafer, or handle wafer, the method comprising, after the attached individual chips have been bonded to the handle wafer, a flow protocol for thinning the rear substrate of the individual chips attached to the handle wafer, which comprises:
a pre-thinning grinding of the rear substrate of the individual chips attached to the handle wafer, preceded by the formation of a first protective layer protecting the trenches formed by spaces between the individual chips attached to the handle wafer, which are not affected by said pre-thinning grinding;
followed by rectification etching to rectify the height of the rear substrate of each of the individual chips attached to the handle wafer, this being performed by chemical wet etching of said substrates, said chemical wet etching being selective with respect to an etch-stop element contained in the substrates and which is used to stop the etching at a level that is substantially uniform for each of said chips.

2. The method according to claim 1, further comprising, between the pre-thinning grinding and the rectification etching, the formation of a second protective layer protecting the trenches formed by the spaces between the individual chips attached to the handle wafer, which are not affected by said rectification etching.

3. The method according to claim 2, further comprising the removal of the second protective layer only at the planar portions of the rear substrate of the attached individual chips, by etching through a mask obtained beforehand by photolithography of a layer of photosensitive resin, in order to selectively uncover the rear substrate of said chips so that these can undergo the chemical wet rectification etching.

4. The method according to claim 1, wherein the material of the first protective layer and/or the material of the second protective layer are materials based on a nitride.

5. The method according to claim 1, wherein the chemical wet rectification etching is performed using, by way of etch-stop elements, a zone that has a particular doping in the rear substrate of each of the attached individual chips, which zone is created in said substrates at a determined depth, which depth is substantially identical for each of said chips.

6. The method according to claim 5, wherein the particular doping of the zone of the rear substrate of each of the attached individual chips that is used as the etch-stop element for the chemical wet etching is a P-type doping different from the standard P-type doping of said rear substrate.

7. The method according to claim 1, wherein, with the rear substrate of each of the attached individual chips being a composite substrate, the chemical wet rectification etching is performed using, by way of etch-stop elements, a layer of the composite substrate of each of the attached individual chips, which layer is made of a specific material at a determined depth in said composite substrates, which depth is substantially identical for each of said chips.

8. The method according to claim 7, wherein the specific material from which the etch-stop elements for the chemical wet rectification etching are produced is a material based on gallium arsenide (GaAs) or based on aluminium.

9. The method according to claim 1, wherein, with the rear substrate of each of the attached individual chips being an epitaxial silicon substrate a few microns thick, the chemical wet rectification etching is performed using, by way of etch-stop elements, a thin layer of the epitaxial silicon substrate of each of the attached individual chips, which layer is made of a specific material at a determined depth in said substrates, which depth is substantially identical for each of said chips.

10. The method according to claim 9, wherein the thin layer used as etch-stop element for the chemical wet rectification etching is a thin layer of silicon oxide (SiO2) or a thin layer of silicon nitride (Si3N4).

11. The method according to a claim 1, wherein, with the rear substrate of each of the attached individual chips being a Silicon-on-Insulator, or SOI, substrate, the chemical wet rectification etching is performed using, by way of etch-stop elements, a buried layer buried in the SOI substrate of each of the attached individual chips, which layer is made at a determined depth in said SOI substrates, which depth is identical for each of said chips.

12. The method according to claim 11, wherein the buried layer in the SOI substrate of each of the attached individual chips, which layer is used as etch-stop element in the chemical wet rectification etching, is a Buried Oxide, or BOX, layer of said substrate.

13. The method according to claim 1, wherein the attached individual chips are chips that have previously been diced from the one same single donor semiconductor wafer.

14. The method according to claim 1, wherein the handle wafer is a wafer made using traditional CMOS technology.

15. The method according to claim 1, wherein the pre-thinning of the rear substrate of the individual chips attached to the handle wafer is performed using grinding.

16. The method according to claim 1, wherein the pre-thinning of the rear substrate of the individual chips attached to the handle wafer is performed using a method known by the name of SmartCut™ comprising the implantation of ions and a splitting anneal.

17. The method according to claim 1, wherein the individual chips are triaged, prior to being added to the handle wafer, on the basis of the results of a test, so as to set aside any chips that are not functional and add to the handle wafer by bonding only chips that are functional.

18. The method according to claim 17, wherein the test is a test of correct electrical functioning of the chips.

19. A colour imager of BSI (BackSide Illumination) type, comprising a microelectronics device with an array of photosensitive elements, wherein:
the photosensitive elements are individual chips attached to a semiconductor wafer, or handle wafer; and,
the rear substrate of the individual chips attached to the handle substrate has been processed by implementing the method according to claim 1,
the imager further comprising an array of colour filters and an array of microlenses which are produced over the top of the microelectronics device.

20. The method according to claim 4, wherein the nitride is silicon nitride.
